(19) United States
(12) Patent Application Publication
(10) Pub. No.: US 2026/0344401 A1
(43) Pub. Date: Oct. 29, 2026

(54) MICROELECTRONIC DEVICES, MEMORY DEVICES, AND ASSOCIATED METHODS

(71) Applicant: Micron Technology, Inc., Boise, ID (US)

(72) Inventor: Scott L. Light, Boise, ID (US)

(21) Appl. No.: 19/631,875

(22) Filed: Mar. 27, 2026

Related U.S. Application Data
(60) Provisional application No. 63/794,966, filed on Apr. 25, 2025.

(51) Int. Cl. H10W 20/41; G11C 5/06; H10D 30/01; H10D 30/63; H10W 42/20

(52) U.S. Cl. CPC H10W 20/423; G11C 5/063; H10D 30/025; H10D 30/63; H10W 42/267

(57) ABSTRACT

The microelectronic device includes two end of array (EOA) regions. The microelectronic device includes an array region laterally interposed between the two EOA regions in a first direction. The microelectronic device also includes vertical channel access devices within the array region. The vertical channel access devices include a semiconductor pillar comprising a channel region vertically interposed between two source/drain regions. The vertical channel access devices further include a gate electrode structure laterally offset from the semiconductor pillar in a second direction orthogonal to the first direction. The gate electrode structure includes a first portion substantially linearly extending through the array region in the first direction and a second portion continuous with the first portion and horizontally extending in a non-linear path within one of the two EOA regions. The vertical channel access devices also include gate dielectric material horizontally interposed between the gate structure and the semiconductor pillar.

### CROSS-REFERENCE TO RELATED APPLICATIONS

This application claims the benefit under 35 U.S.C. § 119(e) of U.S. Provisional Patent Application Ser. No. 63/794,966, filed Apr. 25, 2025, the disclosure of which is hereby incorporated herein in its entirety by this reference.

### TECHNICAL FIELD

The disclosure, in various embodiments, relates generally to the field of microelectronic device design and fabrication. More specifically, the disclosure relates to methods of forming microelectronic devices and to related microelectronic devices and electronic systems.

### BACKGROUND

Microelectronic device designers often desire to increase the level of integration or density of features within a microelectronic device by reducing the dimensions of the individual features and by reducing the separation distance between neighboring features. In addition, microelectronic device designers often desire to design architectures that are not only compact, but offer performance advantages, as well as simplified designs.

One example of a microelectronic device is a memory device. Memory devices are generally provided as internal integrated circuits in computers or other electronic devices. There are many types of memory devices including, but not limited to, volatile memory devices, such as dynamic random-access memory (DRAM) devices; and non-volatile memory devices such as NAND Flash memory devices. A typical memory cell of a DRAM device includes one access device, such as a transistor, and one memory storage structure, such as a capacitor. Modern applications for semiconductor devices can employ significant quantities of memory cells, arranged in memory arrays exhibiting rows and columns of the memory cells. The memory cells may be electrically accessed through digit lines (e.g., bit lines, data lines) and word lines (e.g., access lines) arranged along the rows and columns of the memory cells of the memory arrays. Memory arrays can be two-dimensional (2D) so as to exhibit a single deck (e.g., a single tier, a single level) of the memory cells, or can be three-dimensional (3D) so as to exhibit multiple decks (e.g., multiple levels, multiple tiers) of the memory cells.

Control logic devices within a base control logic structure underlying a memory array of a memory device have been used to control operations (e.g., access operations, read operations, write operations) of the memory cells of the memory device. An assembly of the control logic devices may be provided in electrical communication with the memory cells of the memory array by way of routing and interconnect structures. However, processing conditions (e.g., temperatures, pressures, materials) for the formation of the memory array over the base control logic structure can limit the configurations and performance of the control logic devices within the base control logic structure. In addition, the quantities, dimensions, and arrangements of the different control logic devices employed within the base control logic structure can also undesirably impede reductions to the size (e.g., horizontal footprint) of the memory device, and/or improvements in the performance (e.g., faster memory cell ON/OFF speed, lower threshold switching voltage requirements, faster data transfer rates, lower power consumption) of the memory device. Furthermore, as the density and complexity of the memory array have increased, so has the complexity of the control logic devices. In some instances, the control logic devices consume more real estate than the memory devices, reducing the memory density of the memory device. Moreover, capacitors for regulating and supplying voltages to the control logic devices can require substantial footprints.

### BRIEF DESCRIPTION OF THE DRAWINGS

FIG. 1 illustrates a simplified, perspective view of a microelectronic device structure at a processing stage of a method of forming a microelectronic device, according to one or more embodiments of the disclosure;

FIG. 2 illustrates a simplified, perspective view of the microelectronic device structure first introduced with reference to FIG. 1 at a subsequent processing stage of the method of forming a microelectronic device following the processing stage of FIG. 1, according to one or more embodiments of the disclosure;

FIG. 3A illustrates a simplified, top-down view of the microelectronic device structure first introduced with reference to FIG. 1 at a subsequent processing stage of the method of forming a microelectronic device following the processing stage of FIG. 2, according to one or more embodiments of the disclosure;

FIG. 3B illustrates a simplified vertical cross-sectional view of the microelectronic device at the processing stage of FIG. 3A;

FIG. 4A illustrates a simplified, top-down view of the microelectronic device structure first introduced with reference to FIG. 1 at a subsequent processing stage of the method of forming a microelectronic device following the processing stage of FIGS. 3A and 3B, according to one or more embodiments of the disclosure;

FIG. 4B illustrates a simplified vertical cross-sectional view of the microelectronic device structure at the processing stage of FIG. 4A;

FIG. 5 illustrates a simplified, perspective view of the microelectronic device structure at the processing stage of FIGS. 4A and 4B;

FIG. 6A illustrates a simplified, top-down view of the microelectronic device structure first introduced with reference to FIG. 1 at a subsequent processing stage of the method of forming a microelectronic device following the processing stage of FIGS. 4A, 4B, and 5, according to one or more embodiments of the disclosure;

FIGS. 6B and 6C illustrate simplified vertical cross-sectional views of the microelectronic device structure at the processing stage of FIG. 6A;

FIG. 7A illustrates a simplified, top-down view of the microelectronic device structure first introduced with reference to FIG. 1 at a subsequent processing stage of the method of forming a microelectronic device following the processing stage of FIGS. 6A and 6B, according to one or more embodiments of the disclosure;

FIG. 7B illustrates a simplified vertical cross-sectional view of the microelectronic device structure at the processing stage of FIG. 7A;

FIG. 8 illustrates a simplified, perspective view of the microelectronic device structure at the processing stage of FIGS. 7A and 7B;

FIG. 9A illustrates a simplified, top-down view of the microelectronic device structure first introduced with reference to FIG. 1 at a subsequent processing stage of the method of forming a microelectronic device following the processing stage of FIGS. 7A, 7B, and 8, according to one or more embodiments of the disclosure;

FIG. 9B illustrates a simplified vertical cross-sectional view of the microelectronic device structure at the processing stage of FIG. 9A;

FIG. 10A illustrates a simplified, top-down view of the microelectronic device structure first introduced with reference to FIG. 1 at a subsequent processing stage of the method of forming a microelectronic device following the processing stage of FIGS. 9A and 9B, according to one or more embodiments of the disclosure;

FIG. 10B illustrates a simplified vertical cross-sectional view of the microelectronic device structure at the processing stage of FIG. 10A;

FIG. 11A illustrates a simplified, top-down view of the microelectronic device structure first introduced with reference to FIG. 1 at a subsequent processing stage of the method of forming a microelectronic device following the processing stage of FIGS. 10A and 10B, according to one or more embodiments of the disclosure;

FIG. 11B illustrates a simplified vertical cross-sectional view of the microelectronic device structure at the processing stage of FIG. 11A;

FIG. 12A illustrates a simplified, top-down view of the microelectronic device structure first introduced with reference to FIG. 1 at a subsequent processing stage of the method of forming a microelectronic device following the processing stage of FIGS. 11A and 11B, according to one or more embodiments of the disclosure;

FIGS. 12B through 13B illustrate simplified vertical cross-sectional views of the microelectronic device structure first introduced with reference to FIG. 1 at different, subsequent processing stages of the method of forming a microelectronic device following the processing stage of FIG. 12A, according to one or more embodiments of the disclosure;

FIG. 14 shows a schematic top view of a microelectronic device at a processing stage of a microelectronic device formed through the method of forming a microelectronic device described with reference to FIGS. 1 through 13B, according to one or more embodiments of the disclosure;

FIG. 15 illustrates an enlarged view of an edge of the array region of a microelectronic device, according to one or more embodiments of the disclosure; and

FIG. 16 is a schematic block diagram of an electronic system, in accordance with an embodiment of the disclosure.

### DETAILED DESCRIPTION

The illustrations included herewith are not meant to be actual views of any particular system, microelectronic structure, microelectronic device, or integrated circuits thereof, but are merely idealized representations that are employed to describe embodiments herein. Elements and features common between figures may retain the same numerical designation except that, for ease of following the description, reference numerals begin with the number of the drawing on which the elements are introduced or most fully described.

The following description provides specific details, such as material types, material thicknesses, and processing conditions in order to provide a thorough description of embodiments described herein. However, a person of ordinary skill in the art will understand that the embodiments disclosed herein may be practiced without employing these specific details. Indeed, the embodiments may be practiced in conjunction with conventional fabrication techniques employed in the semiconductor industry. In addition, the description provided herein does not form a complete process flow for manufacturing a microelectronic device (e.g., a semiconductor device, a memory device), apparatus, or electronic system, or a complete microelectronic device, apparatus, or electronic system. The structures described below do not form a complete microelectronic device, apparatus, or electronic system. Only those process acts and structures necessary to understand the embodiments described herein are described in detail below. Additional acts to form a complete microelectronic device, apparatus, or electronic system from the structures may be performed by conventional techniques.

As used herein, the term “homogeneous” means relative amounts of elements included in a feature (e.g., a material, a structure) do not vary throughout different portions (e.g., different horizontal portions, different vertical portions) of the feature. Conversely, as used herein, the term “heterogeneous” means relative amounts of elements included in a feature (e.g., a material, a structure) vary throughout different portions of the feature. If a feature is heterogeneous, amounts of one or more elements included in the feature may vary stepwise (e.g., change abruptly), or may vary continuously (e.g., change progressively, such as linearly, parabolically) throughout different portions of the feature. The feature may, for example, be formed of and include a stack of at least two different materials.

As used herein, the term “configured” refers to a size, shape, material composition, orientation, and arrangement of one or more of at least one structure and at least one apparatus facilitating operation of one or more of the structure and the apparatus in a predetermined way.

As used herein, the terms “longitudinal,” “vertical,” “lateral,” and “horizontal” are in reference to a major plane of a substrate (e.g., base material, base structure, base construction, etc.) in or on which one or more structures and/or features are formed and are not necessarily defined by Earth's gravitational field. A “lateral” or “horizontal” direction is a direction that is substantially parallel to the major plane of the substrate, while a “longitudinal” or “vertical” direction is a direction that is substantially perpendicular to the major plane of the substrate. The major plane of the substrate is defined by a surface of the substrate having a relatively large area compared to other surfaces of the substrate. With reference to the figures, a “horizontal” or “lateral” direction may be perpendicular to an indicated “Z” axis, and may be parallel to an indicated “X” axis and/or parallel to an indicated “Y” axis; and a “vertical” or “longitudinal” direction may be parallel to an indicated “Z” axis, may be perpendicular to an indicated “X” axis, and may be perpendicular to an indicated “Y” axis.

As used herein, the term “substantially” in reference to a given parameter, property, or condition means and includes to a degree that one of ordinary skill in the art would understand that the given parameter, property, or condition is met with a degree of variance, such as within acceptable tolerances. By way of example, depending on the particular parameter, property, or condition that is substantially met, the parameter, property, or condition may be at least 90.0 percent met, at least 95.0 percent met, at least 99.0 percent met, at least 99.9 percent met, or even 100.0 percent met.

As used herein, “about” or “approximately” in reference to a numerical value for a particular parameter is inclusive of the numerical value and a degree of variance from the numerical value that one of ordinary skill in the art would understand is within acceptable tolerances for the particular parameter. For example, “about” or “approximately” in reference to a numerical value may include additional numerical values within a range of from 90.0 percent to 110.0 percent of the numerical value, such as within a range of from 95.0 percent to 105.0 percent of the numerical value, within a range of from 97.5 percent to 102.5 percent of the numerical value, within a range of from 99.0 percent to 101.0 percent of the numerical value, within a range of from 99.5 percent to 100.5 percent of the numerical value, or within a range of from 99.9 percent to 100.1 percent of the numerical value.

As used herein, the term “proximate,” when utilized to describe positions of elements relative to each other, means that the elements are relatively close or near to each other. For example, where a first element is proximate a horizontal boundary of a second element, the first element is closer to that horizontal boundary than other horizontal boundaries of the second element.

As used herein, spatially relative terms, such as “beneath,” “below,” “lower,” “bottom,” “above,” “upper,” “top,” “front,” “rear,” “left,” “right,” and the like, may be used for ease of description to describe one element's or feature's relationship to another element(s) or feature(s) as illustrated in the figures. Unless otherwise specified, the spatially relative terms are intended to encompass different orientations of the materials in addition to the orientation depicted in the figures. For example, if materials in the figures are inverted, elements described as “below” or “beneath” or “under” or “on bottom of” other elements or features would then be oriented “above” or “on top of” the other elements or features. Thus, the term “below” can encompass both an orientation of above and below, depending on the context in which the term is used, which will be evident to one of ordinary skill in the art. The materials may be otherwise oriented (e.g., rotated 90 degrees, inverted, flipped, etc.) and the spatially relative descriptors used herein interpreted accordingly.

As used herein, features (e.g., regions, materials, structures, devices) described as “neighboring” one another means and includes features of the disclosed identity (or identities) that are located most proximate (e.g., closest to) one another. Additional features (e.g., additional regions, additional materials, additional structures, additional devices) not matching the disclosed identity (or identities) of the “neighboring” features may be disposed between the “neighboring” features. Put another way, the “neighboring” features may be positioned directly adjacent one another, such that no other feature intervenes between the “neighboring” features; or the “neighboring” features may be positioned indirectly adjacent one another, such that at least one feature having an identity other than that associated with at least one the “neighboring” features is positioned between the “neighboring” features. Accordingly, features described as “vertically neighboring” one another means and includes features of the disclosed identity (or identities) that are located most vertically proximate (e.g., vertically closest to) one another. Moreover, features described as “horizontally neighboring” one another means and includes features of the disclosed identity (or identities) that are located most horizontally proximate (e.g., horizontally closest to) one another.

As used herein, the term “memory device” means and includes microelectronic devices exhibiting memory functionality, but not necessarily limited to memory functionality. Stated another way, and by way of example only, the term “memory device” means and includes not only conventional memory (e.g., conventional volatile memory, such as conventional DRAM; conventional non-volatile memory, such as conventional NAND memory), but also includes an application specific integrated circuit (ASIC) (e.g., a system on a chip (SoC)), a microelectronic device combining logic and memory, and a graphics processing unit (GPU) incorporating memory.

As used herein, “conductive material” means and includes electrically conductive material such as one or more of a metal (e.g., tungsten (W), titanium (Ti), molybdenum (Mo), niobium (Nb), vanadium (V), hafnium (Hf), tantalum (Ta), chromium (Cr), zirconium (Zr), iron (Fe), ruthenium (Ru), osmium (Os), cobalt (Co), rhodium (Rh), iridium (Ir), nickel (Ni), palladium (Pd), platinum (Pt), copper (Cu), silver (Ag), gold (Au), aluminum (Al)), an alloy (e.g., a Co-based alloy, an Fe-based alloy, an Ni-based alloy, an Fe- and Ni-based alloy, a Co- and Ni-based alloy, an Fe- and Co-based alloy, a Co- and Ni- and Fe-based alloy, an Al-based alloy, a Cu-based alloy, a magnesium (Mg)-based alloy, a Ti-based alloy, a steel, a low-carbon steel, a stainless steel), a conductive metal-containing material (e.g., a conductive metal nitride, a conductive metal silicide, a conductive metal carbide, a conductive metal oxide), and a conductively-doped semiconductor material (e.g., conductively-doped polysilicon, conductively-doped germanium (Ge), conductively-doped silicon germanium (SiGe)). In addition, a “conductive structure” means and includes a structure formed of and including a conductive material.

As used herein, “insulative material” means and includes electrically insulative material, such one or more of at least one dielectric oxide material (e.g., one or more of a silicon oxide (SiOₓ), phosphosilicate glass, borosilicate glass, borophosphosilicate glass, fluorosilicate glass, an aluminum oxide (AlOₓ), a hafnium oxide (HfOₓ), a niobium oxide (NbOₓ), a titanium oxide (TiOₓ), a zirconium oxide (ZrOₓ), a tantalum oxide (TaOₓ), and a magnesium oxide (MgOₓ)), at least one dielectric nitride material (e.g., a silicon nitride (SiN_{y})), at least one dielectric oxynitride material (e.g., a silicon oxynitride (SiOₓN_{y})), and at least one dielectric carboxynitride material (e.g., a silicon carboxynitride (SiOₓC_{z}N_{y})). In addition, an “insulative structure” means and includes a structure formed of and including an insulative material.

As used herein, the term “sacrificial material” means and includes a material that is formed and/or employed during a fabrication process but which is subsequently removed, in whole or in part, prior to completion of the fabrication process. A “partially-sacrificial” material means and includes a sacrificial material from which only one or more portions is or are removed prior to completion of the fabrication process. A “wholly-sacrificial” material means and includes a sacrificial material that is substantially entirely removed prior to completion of the fabrication process.

As used herein, “semiconductor material” and “semiconductive material” refers to a material having an electrical conductivity between those of insulative materials and conductive materials. For example, a semiconductor material may have an electrical conductivity of between about 10⁻⁸ Siemens per centimeter (S/cm) and about 10⁴ S/cm (10⁶ S/m) at room temperature. Examples of semiconductor materials include elements found in column IV of the periodic table of elements such as silicon (Si), germanium (Ge), and carbon (C). Other examples of semiconductor materials include compound semiconductor materials such as binary compound semiconductor materials (e.g., gallium arsenide (GaAs)), ternary compound semiconductor materials (e.g., Al_{X}Ga_{1-X}As), and quaternary compound semiconductor materials (e.g., Ga_{X}In_{1-X}As_{Y}P_{1-Y}), without limitation. Compound semiconductor materials may include combinations of elements from columns III and V of the periodic table of elements (III-V semiconductor materials) or from columns II and VI of the periodic table of elements (II-VI semiconductor materials), without limitation. Further examples of semiconductor materials include oxide semiconductor materials such as zinc tin oxide (ZnₓSn_{y}O, commonly referred to as “ZTO”), indium zinc oxide (InₓZn_{y}O, commonly referred to as “IZO”), zinc oxide (ZnₓO), indium gallium zinc oxide (InₓGa_{y}Zn_{z}O, commonly referred to as “IGZO”), indium gallium silicon oxide (InₓGa_{y}Si_{z}O, commonly referred to as “IGSO”), indium tungsten oxide (InₓW_{y}O, commonly referred to as “IWO”), indium oxide (InₓO), tin oxide (SnₓO), titanium oxide (TiₓO), zinc oxide nitride (ZnₓON_{z}), magnesium zinc oxide (MgₓZn_{y}O), zirconium indium zinc oxide (ZrₓIn_{y}Zn_{z}O), hafnium indium zinc oxide (HfₓIn_{y}Zn_{z}O), tin indium zinc oxide (SnₓIn_{y}Zn_{z}O), aluminum tin indium zinc oxide (AlₓSn_{y}In_{z}ZnₐO), silicon indium zinc oxide (SiₓIn_{y}Zn_{z}O), aluminum zinc tin oxide (AlₓZn_{y}Sn_{z}O), gallium zinc tin oxide (GaₓZn_{y}Sn_{z}O), zirconium zinc tin oxide (ZrₓZn_{y}Sn_{z}O), and other similar materials.

Formulae including one or more of “x,” “y,” and “z” herein (e.g., SiOₓ, AlOₓ, HfOₓ, NbOₓ, TiOₓ, SiN_{y}, SiOₓN_{y}, SiOₓC_{z}N_{y}) represent a material that contains an average ratio of “x” atoms of one element, “y” atoms of another element, and “z” atoms of an additional element (if any) for every one atom of another element (e.g., Si, Al, Hf, Nb, Ti). As the formulae are representative of relative atomic ratios and not strict chemical structure, an insulative material may comprise one or more stoichiometric compounds and/or one or more non-stoichiometric compounds, and values of “x,” “y,” and “z” (if any) may be integers or may be non-integers. As used herein, the term “non-stoichiometric compound” means and includes a chemical compound with an elemental composition that cannot be represented by a ratio of well-defined natural numbers and is in violation of the law of definite proportions.

Unless the context indicates otherwise, the materials described herein may be formed by any suitable technique including, but not limited to, spin coating, blanket coating, chemical vapor deposition (CVD), plasma enhanced CVD (PECVD), atomic layer deposition (ALD), plasma enhanced ALD (PEALD), physical vapor deposition (PVD) (e.g., sputtering), or epitaxial growth. Depending on the specific material to be formed, the technique for depositing or growing the material may be selected by a person of ordinary skill in the art. In addition, unless the context indicates otherwise, removal of materials described herein may be accomplished by any suitable technique including, but not limited to, etching (e.g., dry etching, wet etching, vapor etching), ion milling, abrasive planarization (e.g., chemical-mechanical planarization (CMP)), or other known methods.

As discussed above, when reducing the size of microelectronic devices processing conditions (e.g., temperatures, pressures, materials) for the formation of the memory array over the base control logic structure can limit the configurations and performance of the control logic devices within the base control logic structure. In some cases, the base control logic structure is formed separate from the memory array and the base control logic structure and the memory array are joined together in a subsequent step, such as through wafer to wafer bonding. The separate formation may reduce the temperatures and pressures experienced by the base control logic structure and memory array. However, small differences in location of the components of the base control logic structure and the memory array may be exacerbated when joining the two structures. Embodiments of the disclosure provide connecting structures at the edges of the array that accommodate greater differences in a location of the complementary connecting structures of a secondary structure to reduce connection failures between the connecting structures and complementary connecting structures of the memory array and the control logic structure.

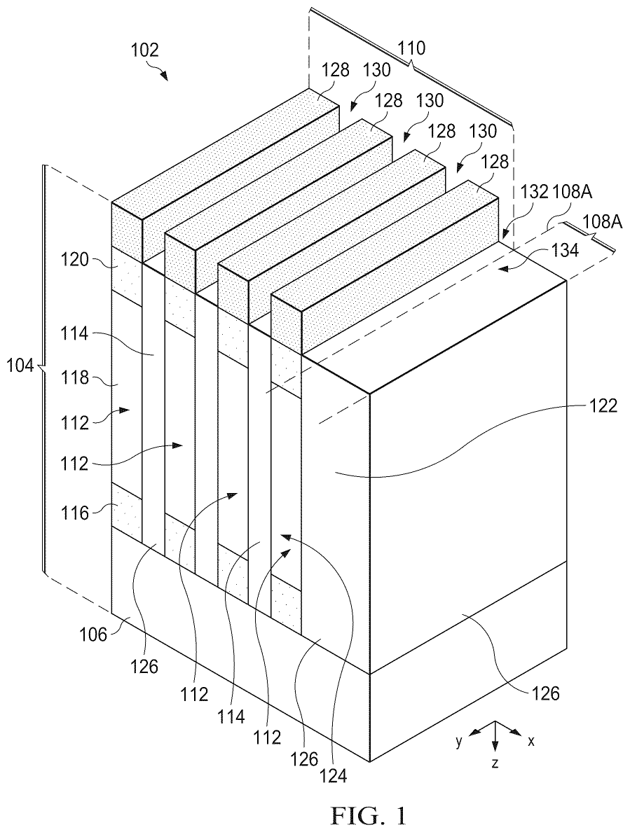

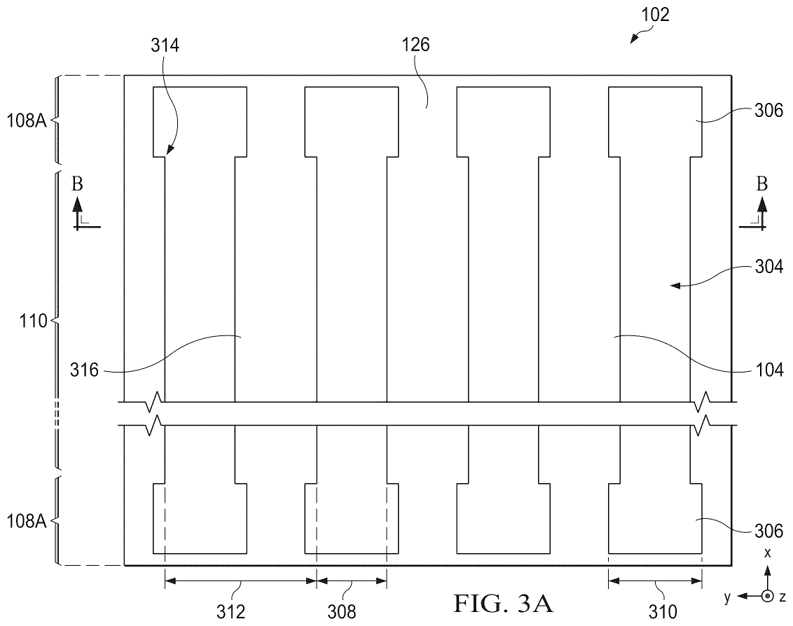

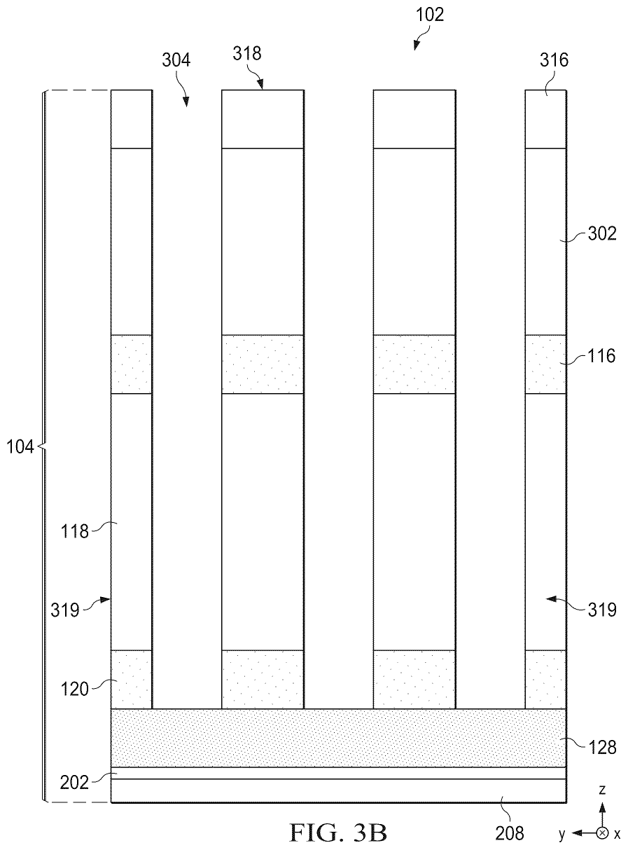

FIG. 1 through FIG. 13B illustrate simplified perspective views (i.e., FIGS. 1, 2, 5, 8), simplified top-down views (i.e., FIGS. 3A, 4A, 6A, 7A, 9A, 10A, 11A), and simplified vertical cross-sectional views (i.e., FIGS. 3B, 4B, 6B, 6C, 7B, 9B, 10B, 11B, 12A, 12B, 12C, 13A, 13B) of a memory array structure 102 at different processing stages of a method of forming a microelectronic device (e.g., a memory device, such as Dynamic Random Access Memory (DRAM) device, a Hierarchical Random Access Memory (HRAM) device, a Ferroelectric Random Access Memory (FeRAM) device, a Synchronous Dynamic Random Access Memory (SDRAM) device, a Magnetoresistive Random Access Memory (MRAM) device), in accordance with embodiments of the disclosure. With the description provided below, it will be readily apparent to one of ordinary skill in the art that the methods described herein may be used for forming various devices.

Referring to FIG. 1, forming the memory array structure 102 may include forming a first assembly 104. The first assembly 104 may also be referred to herein as a die or a wafer. The first assembly 104 may at least include a semiconductor structure (e.g., a semiconductor wafer), or a base semiconductive material on a support structure or construction upon which additional materials and structures of the memory array structure 102 are formed. For example, the first assembly 104 may include a first carrier structure 106 including one or more of a semiconductor (e.g., silicon) structure (e.g., substrate), a ceramic structure, and an insulative structure.

The memory array structure 102 may include an array region 110 horizontally adjacent to a first edge of the array region 108A in the X-direction. Put another way, the array region 110 may horizontally neighbor the first edge of the array region 108A in the X-direction. In particular, the first edge of the array region 108A may be defined at horizontal edges of neighboring patch regions or bank regions of the memory array structure 102.

The memory array structure 102 may include semiconductor projections 112 extending from an upper surface of the first carrier structure 106 and formed on or over the first carrier structure 106. The semiconductor projections 112 may include a semiconductor material. In some embodiments, the first carrier structure 106 and the semiconductor projections 112 may together form a silicon-over-insulator (SOI) substrate. The semiconductor projections 112 are positioned within the array region 110, and the first edge of the array region 108A is substantially free of the semiconductor projections 112. The semiconductor projections 112 may be laterally spaced apart from one another by y-axis trenches 114 extending vertically (e.g., in the Z-direction) into the first assembly 104 and between neighboring semiconductor projections 112 of the memory array structure 102. The y-axis trenches 114 may extend horizontally in parallel in the Y-direction (e.g., a first direction). The y-axis trenches 114 may have any suitable dimensions. In some embodiments, the y-axis trenches 114 have vertical depths (e.g., vertical heights) within a range of from about 100 nm to about 200 nm (e.g., about 145 nm).

The semiconductor projections 112 may include silicon structures, such as an epitaxial silicon structures. Additionally, each of the semiconductor projections 112 may include a first doped region 116 vertically overlying the first carrier structure 106, an undoped region 118 vertically overlying the first doped region 116, and a second doped region 120 vertically overlying the undoped region 118. In some embodiments, each of the first doped region 116 and the second doped region 120 are n-type doped, such as N-type doped to an N-type dopant concentration within a range of from about 10¹⁵ cm⁻³ to about 10²⁰ cm⁻³. In additional embodiments, one of the first doped region 116 and the second doped region 120 is N-type doped while the other of the first doped region 116 and the second doped region 120 may be P-type doped, such as P-type doped to a P-type dopant concentration within a range of from about −10¹³ cm⁻³ to about −10¹⁸ cm⁻³. In additional embodiments, one or more of the first doped region 116 and the second doped region 120 is doped (either P-doped or N-doped) to the point of saturation (e.g., greater than or equal to about −10¹⁸ cm⁻³). The doping may be accomplished utilizing any suitable processing, such as by implanting dopant (e.g., at least one N-type dopant or at least one P-type dopant) into the semiconductor projections 112 or a structure formed into the semiconductor projections 112. A P-type dopant may include one or more of boron, aluminum, and gallium; and an N-type dopant may include one or more of arsenic, phosphorous, antimony, and bismuth.

In some embodiments, the undoped region 118 does not include any P-type dopants or any N-type dopants. In alternative embodiments, the undoped region 118 is doped with one of the dopants described herein and becomes another doped region. In such embodiments, a dopant type of the undoped region 118 is different than dopant types of the first doped region 116 and the second doped region 120. For example, if the first doped region 116 and the second doped region 120 respectively include semiconductor material (e.g., epitaxial silicon) doped with at least one N-type dopant, the undoped region 118 may include the semiconductor material (e.g., epitaxial silicon) doped with at least one P-type dopant.

In one or more embodiments, the first doped region 116 forms a drain region of a later-formed vertical channel access device (VCAD) (e.g., vertical channel transistor (VCT)), the undoped region 118 forms a channel region of the later-formed VCAD, and the second doped region 120 forms a source region of the later-formed VCAD.

The memory array structure 102 may include a separation trench 122 formed within the first edge of the array region 108A and spanning an interface of the memory array structure 102 with the first edge of the array region 108A. For example, a vertical side surface of a semiconductor projection 112 of the memory array structure 102 most proximate the first edge of the array region 108A in the X-direction may define a first horizontal boundary of the separation trench 122 in the X-direction. The semiconductor projection 112 most proximate the first edge of the array region 108A in the X-direction may be referred to herein as an “outermost semiconductor projection 124.”

In some embodiments, a second horizontal boundary of the separation trench 122 in the X-direction is defined by a semiconductor projection of another memory array structure on an opposite side of the first edge of the array region 108A. For example, the memory array structure 102 and the another memory array structure may be formed on opposing sides of the first edge of the array region 108A of the microelectronic device in the X-direction. Put another way, each of the memory array structure 102 and the another memory array structure may horizontally neighbor and flank the first edge of the array region 108A of the microelectronic device (e.g., edge of die) in the X-direction.

In additional embodiments, the separation trench 122 does not have a defined second horizontal boundary in the X-direction. For example, the separation trench 122 may be open to a horizontal lateral side of the memory array structure 102. In particular, the separation trench 122 may form a so called “cutout” that is accessible from an upper surface of the memory array structure 102 and an adjacent lateral side surface of the memory array structure 102.

A first isolation material 126 may be formed within the y-axis trenches 114 and within the separation trench 122 within the first edge of the array region 108A of the microelectronic device. For instance, the y-axis trenches 114 and the separation trench 122 may be filled with the first isolation material 126. In some embodiments, the first isolation material 126 is formed of and includes a dielectric oxide material, such as SiOₓ (e.g., SiO₂). The first isolation material 126 may be substantially homogeneous, or the first isolation material 126 may be heterogeneous. The first isolation material 126 may, for example, be formed of and include a stack of at least two different dielectric materials. The first isolation material 126 may be formed (e.g., deposited) via and of the manners described herein.

In some embodiments, the first assembly 104 further includes a first dielectric liner material formed in the y-axis trenches 114, over the semiconductor projections 112 of the memory array structure 102, and between the semiconductor projections 112 and the first isolation material 126. The first dielectric liner material may be formed over and alongside surfaces of the semiconductor projections 112 and upper surfaces of the first carrier structure 106 between neighboring semiconductor projections 112.

In one or more embodiments, the first dielectric liner material is also formed within the separation trench 122. Within the separation trench 122, the first dielectric liner material may be formed over an upper surface of first carrier structure 106 extending from the outermost semiconductor projection 124 in the X-direction and into the first edge of the array region 108A of the microelectronic device. The first dielectric liner material may be formed of and include insulative material. In some embodiments, the first dielectric liner material is formed of and includes silicon dioxide.

Referring still to FIG. 1, digit line structures 128 (e.g., bit line structures, data line structures) may be formed on or over the semiconductor projections 112 of the memory array structure 102 of the first assembly 104. In particular, the digit line structures 128 are formed vertically on or over each of the semiconductor projections 112 of the memory array structure 102 of the first assembly 104. The digit line structures 128 may be formed of and include a conductive material. The conductive material may include one or more conductive materials. In some embodiments, the conductive material includes tungsten, either alone or in combination with one or more conductive barrier materials (e.g., oxidation resistant materials which protect the tungsten from oxidation in embodiments in which the tungsten may be exposed to oxygen).

The digit line structures 128 may be formed to any suitable dimensions (e.g., width, thickness). By way of example, the digit line structures 128 may individually be formed to a width, in the X-direction, equal to about the width of an individual semiconductor projection 112 (e.g., in a range of from about 10 nm to about 30 nm). The digit line structures 128 may be formed to any suitable pitch. The digit line structures 128 may be spaced apart from one another by a distance equal to about the distance between the semiconductor projections 112 horizontally neighboring one another in the X-direction.

The digit line structures 128 may be formed using any suitable processing. For instance, the conductive material may be formed on or over the upper surface of the first assembly 104 (e.g., upper surfaces of the first isolation material 126 and the first doped regions 116 of the semiconductor projections 112), and a first mask material may be formed over an upper surface of the conductive material, and the first mask material may be patterned to form patterned masking lines horizontally extending in parallel with one another in the Y-direction. The first mask material may be patterned into the patterned masking lines utilizing any suitable methodology. For instance, in some embodiments, a photoresist material is formed on or over the first mask material, is patterned (e.g., photo exposed and developed), and then openings formed in the patterned photoresist material are extended into the first mask material to form the patterned masking lines.

The patterned masking lines may be employed to form additional y-axis trenches 130 extending vertically through the conductive material formed over the memory array structure 102. The additional y-axis trenches 130 may extend horizontally in parallel in the Y-direction. The additional y-axis trenches 130 may have any suitable dimensions. For instance, the additional y-axis trenches 130 may have a width, in the X-direction, at least substantially equal to about the width of an individual space between neighboring semiconductor projections. In some embodiments, the additional y-axis trenches 130 are formed using an etching process (e.g., an anisotropic etching process) that selectively removes exposed portions of the conductive material relative to the patterned masking lines without removing portions of the first isolation material 126. Accordingly, lower boundaries (e.g., bottoms) of the additional y-axis trenches 130, as defined by upper surfaces of the first isolation material 126, may be substantially planar.

Referring still to FIG. 1, the first mask material may also be utilized to form a second separation trench 132 extending vertically through the conductive material and/or any other materials over the first isolation material 126 within the first edge of the array region 108A and the first isolation material 126 between the first edge of the array region 108A and the outermost semiconductor projection 124. Formation of the second separation trench 132 may expose an upper surface 134 of the first isolation material 126 within the first edge of the array region 108A and the first isolation material 126 between the first edge of the array region 108A and the outermost semiconductor projection 124.

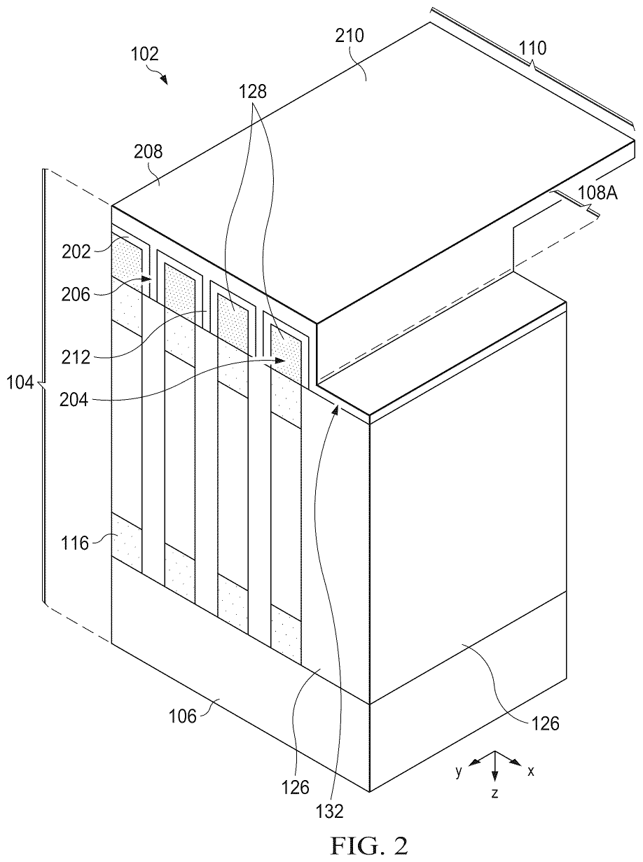

Referring to FIG. 2, a second dielectric liner material 202 may be formed within the additional y-axis trenches 130 (FIG. 1), over the digit line structures 128 and the first isolation material 126 of the memory array structure 102; within the second separation trench 132, over the first isolation material 126 within the first edge of the array region 108A; and over the first isolation material 126 between the first edge of the array region 108A and the outermost semiconductor projection 124. For instance, the second dielectric liner material 202 may be formed (e.g., conformally deposited) inside the additional y-axis trenches 130, over the digit line structures 128, inside the second separation trench 132, over the first isolation material within the first edge of the array region 108A, and over the first isolation material 126 between the first edge of the array region 108A and the second dielectric liner material 202 lining a digit line structure 128 most proximate the first edge of the array region 108A in the X-direction. The digit line structure 128 most proximate the first edge of the array region 108A in the X-direction may be referred to herein as an “outermost digit line structure 204.” In some embodiments, the second dielectric liner material 202 does not entirely fill the additional y-axis trenches 130 or the second separation trench 132. For instance, recesses 206 may remain between portions the second dielectric liner material 202 deposited on the vertical sidewalls of the digit line structures 128 of the memory array structure 102.

Within the additional y-axis trenches 130, the second dielectric liner material 202 may include side portions on the side surfaces of the digit line structures 128, and, optionally, bottom portions on or over the upper surfaces of the first isolation material 126. In some embodiments, portions of the bottom portions of the second dielectric liner material 202 lining the upper surfaces of the first isolation material 126 are removed by way of one or more of any of the removal processes described herein.

The second dielectric liner material 202 may be formed of and include insulative material. In some embodiments, the second dielectric liner material 202 is formed of and includes silicon dioxide. The second dielectric liner material 202 may have a thickness within a range of from about 3 nm to about 7 nm (e.g., about 5 nm).

Referring still to FIG. 2, a shield structure 208 (also referred to herein as a “digit line shield structure”) may be formed over the second dielectric liner material 202 and an exposed surface of the first isolation material 126. For instance, a conductive material 210 may be deposited (e.g., conformally deposited) within the recesses 206, over the second dielectric liner material 202, over upper surfaces of the first isolation material 126 between neighboring digit line structures 128, over an upper surface of the first isolation material within the first edge of the array region 108A, and over an upper surface of the first isolation material 126 between the first edge of the array region 108A and the outermost digit line structure 204. In particular, the conductive material 210 may be deposited over any exposed upper surface of the first isolation material 126 within the second separation trench 132. The conductive material 210 vertically overlying the digit line structures 128 may form the shield structure 208.

The shield structure 208 may at least substantially entirely fill the recesses 206 and cover upper surfaces of the first isolation material 126 extending between horizontally neighboring digit line structures 128. As a result, in some embodiments, the shield structure 208 includes projections 212 extending vertically downward between horizontally neighboring digit line structures 128. Moreover, because the shield structure 208 at least substantially entirely fills the recesses 206, the shield structure 208 may extend vertically in between neighboring digit line structures 128. Put another way, portions of the shield structure 208 may be horizontally interposed between neighboring digit line structures 128 of the memory array structure 102.

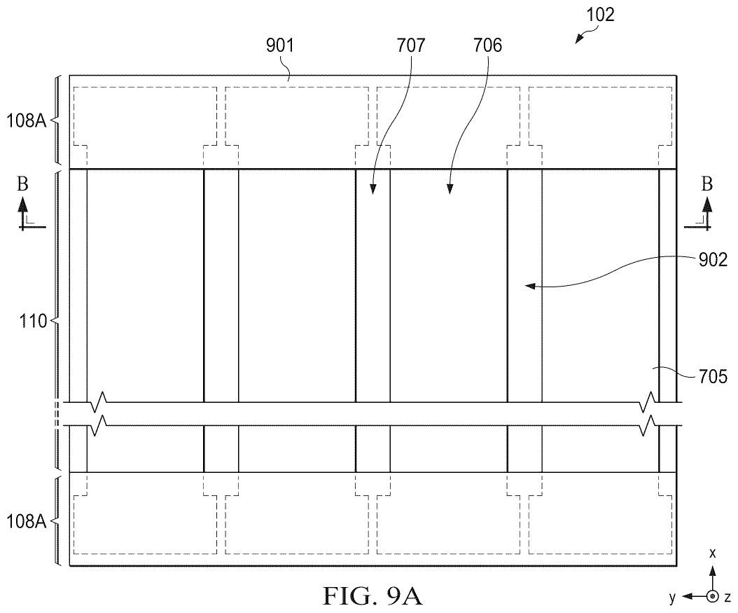

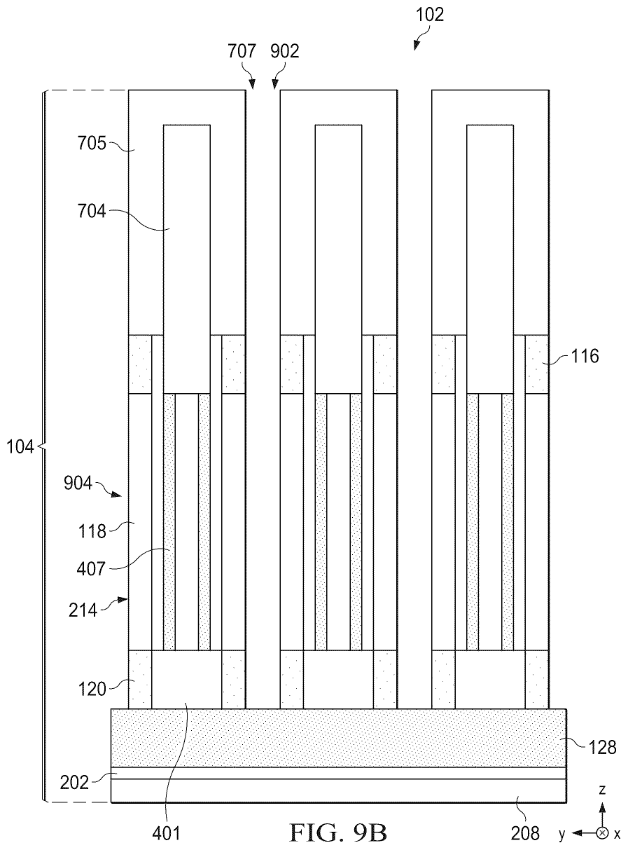

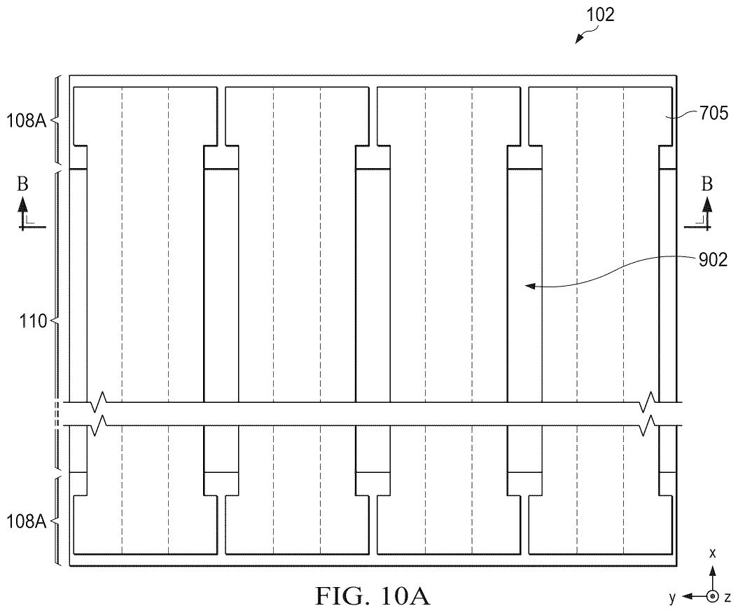

The shield structure 208 (e.g., upper shielding plate, top shielding plate) may be configured and positioned to shield (e.g., protect) features (e.g., structures, materials, devices, digit lines) within portions of memory cells (e.g., vertical channel access devices 214 (FIG. 9B) (described below)) of the memory array structure 102 from undesirable electrical interference (e.g., electromagnetic interference (EMI)).

In some embodiments, the second dielectric liner material 202 at least substantially fills the additional y-axis trenches 130, and the shield structure 208 is formed over a substantially uniform or continuous upper surface of the second dielectric liner material 202. As a result, in some embodiments, the shield structure 208 does not include the projections 212 extending vertically downward between horizontally neighboring digit line structures 128 and, rather, may include a generally flat structure.

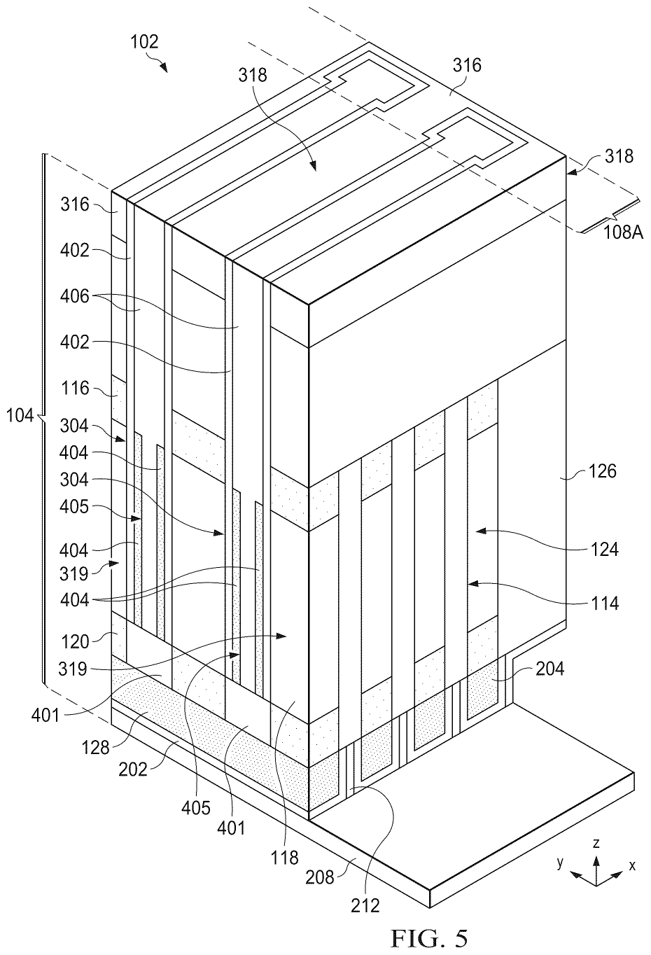

In view of the foregoing, the shield structure 208 may vertically overlie the digit line structures 128 of the memory array structure 102. Accordingly, vertical channel access devices (to be subsequently formed) of the memory array structure 102 may be vertically interposed between the digit line structures 128 and a later-formed multi-storage node structure. The multi-storage node structure may be separately formed and later attached to the memory array structure 102 following subsequent processing of the memory array structure 102 described hereinbelow. The multi-storage node structure may include multiple storage node devices (e.g., capacitors) formed on or over a redistribution layer (RDL) tier and formed redistribution material (RDM) structures. The second assembly may include the first assembly 104 and the multi-storage node structure. The storage node devices may be in electrical contact with the RDM structures, and, hence, with contact structures of the semiconductor projections 112 (e.g., and, hence, vertical channel access devices 214 (FIG. 5)) of the first assembly 104. The storage node devices may be coupled to the semiconductor projections 112 by way of the contact structures and the RDM structures to form memory cells (e.g., DRAM cells). Each memory cell may individually include one of the vertical channel access devices, one of the storage node devices, one of the contact structures, and one of the RDM structures. The storage node devices may individually be formed and configured to store a charge representative of a programmable logic state of the memory cell including the storage node device. In some embodiments, the storage node devices include capacitors. During use and operation, a charged capacitor may represent a first logic state, such as a logic 1; and an uncharged capacitor may represent a second logic state, such as a logic 0. Each of the storage node devices may, for example, be formed to include a first electrode (e.g., a bottom electrode), a second electrode (e.g., a top electrode), and a first dielectric material between the first electrode and the second electrode. For instance, each of the storage node devices may include a metal-insulator-metal (MIM) capacitor. As another example, each of the storage node devices may include a metal-insulator-semiconductor (MIS) capacitor. The collection of memory cells may form a memory array of the memory array structure 102 and microelectronic device.

As noted above, the shield structure 208 may be formed of and include conductive material. In some embodiments, the shield structure 208 is formed of and includes metallic material, such as one or more of at least one metal, at least one alloy, and at least one conductive metal-containing material (e.g., a conductive metal nitride, a conductive metal silicide, a conductive metal carbide, a conductive metal oxide). By way of non-limiting example, the shield structure 208 may be formed of and include tungsten (W). The shield structure 208 may be substantially homogeneous, or the shield structure 208 may be heterogeneous. If the shield structure 208 is heterogeneous, amounts of one or more elements included in the shield structure 208 may vary stepwise (e.g., change abruptly), or may vary continuously (e.g., change progressively, such as linearly, parabolically) throughout different portions of the shield structure 208. The shield structure 208 may, for example, be formed of and include a stack of at least two different conductive materials.

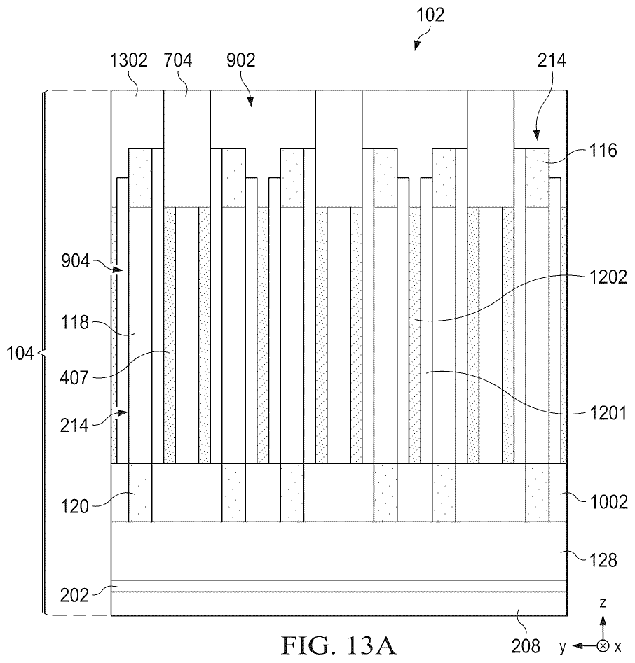

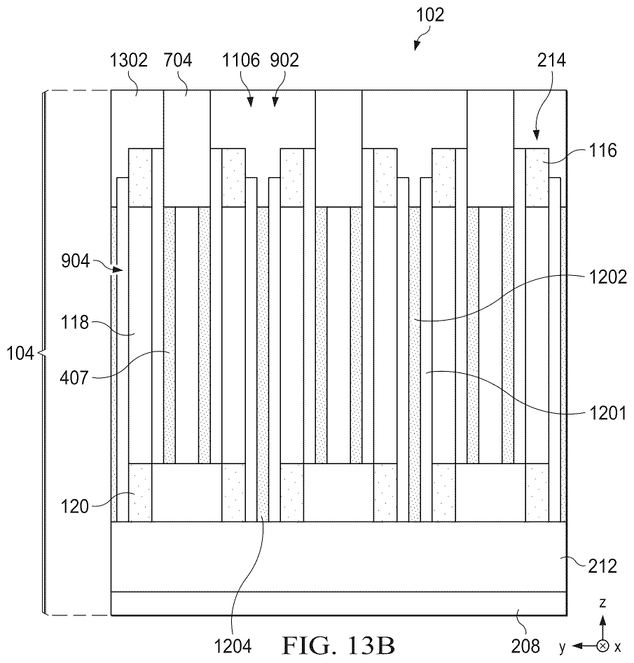

In other embodiments, the formation of the digit line structures 128, the additional y-axis trenches 130 (FIG. 1), the second dielectric liner material 202, and the shield structure 208 (including the projections 212 thereof) is not effectuated until after the processing described hereinbelow with reference to FIGS. 3-13B. Instead, a carrier structure (e.g., a carrier wafer or sacrificial structure) may be employed in place of the digit line structures 128, the additional y-axis trenches 130 (FIG. 1), the second dielectric liner material 202, and the shield structure 208 until after the processing stage described hereinbelow with reference to FIG. 13B. Following the processing stage described hereinbelow with reference to FIG. 13B, the assembly 104 may be vertically inverted, the carrier structure may be removed, and then the digit line structures 128, the additional y-axis trenches 130 (FIG. 1), the second dielectric liner material 202, and the shield structure 208 (including the projections 212 thereof) may be formed. Accordingly, while FIGS. 1-13B illustrate the formation of the digit line structures 128, the additional y-axis trenches 130 (FIG. 1), the second dielectric liner material 202, and the shield structure 208 (including the projections 212 thereof) in advance of the processing stage described with reference to FIG. 13B, it will be understood that the method of forming a microelectronic device of the disclosure may be modified such that the formation of the digit line structures 128, the additional y-axis trenches 130 (FIG. 1), the second dielectric liner material 202, and the shield structure 208 (including the projections 212 thereof) occurs after the processing stage described with reference to FIG. 13B.

Reference is now collectively made to FIGS. 3A and 3B, which are simplified schematic illustrations of the memory array structure 102 in a subsequent processing step. FIG. 3A illustrates a simplified top-down view of the memory array structure 102, and FIG. 3B illustrates a simplified vertical cross-sectional view of the memory array structure 102 along line B-B in FIG. 3A. The first assembly 104 may be vertically inverted such that the semiconductor projections 112 (FIG. 2) vertically overlie the digit line structures 128 and the shield structure 208. In some embodiments, the first assembly 104 is bonded to a second carrier structure prior to being vertically inverted. For example, the second carrier structure may be bonded to upper surfaces the shield structure 208 or another material (e.g., a dielectric material, such as a dielectric oxide material) formed over the shield structure 208 prior to inversion, and the second carrier structure may be utilized to facilitate inversion.

Following inversion of the memory array structure 102, one or more sacrificial structures 302 are formed over the semiconductor projections 112 (FIG. 2) and the first isolation material 126 (FIG. 2), and then additional trenches 304 may be formed to extend vertically into the first assembly 104. In particular, the additional trenches 304 may be formed to extend vertically into the semiconductor projections 112 (FIG. 2) and the first isolation material 126 (FIG. 2) to form semiconductor pillars 319 (e.g., initial semiconductor pillars) from remaining portions of the semiconductor projections 112 (FIG. 2). Each of the semiconductor pillars 319 may respectively include the first doped region 116, the undoped region 118, and the second doped region 120 of semiconductor material. The additional trenches 304 may extend horizontally in parallel in the X-direction (e.g., a second direction) perpendicular to the Y-direction and may be referred to herein as “x-axis trenches 304.”

In some embodiments, the x-axis trenches 304 are formed using a second mask material 316 and an etching process (e.g., an anisotropic etching process) that removes exposed portions of the sacrificial structure 302, the first isolation material 126 (FIG. 2), and the semiconductor projections 112 (FIG. 2). For example, the second mask material 316 may be formed over upper surfaces of the first isolation material 126 (FIG. 2) and the first doped regions 116 of the semiconductor projections 112 (FIG. 2), and the second mask material 316 may be patterned to form second patterned masking lines 318 horizontally extending in parallel with one another in the X-direction. The second mask material 316 may be patterned into the second patterned masking lines 318 utilizing any suitable methodology. For instance, in some embodiments, a photoresist material is formed on or over the second mask material 316, is patterned (e.g., photo exposed and developed), and then openings formed in the patterned photoresist material are extended into the second mask material 316 to form the second patterned masking lines 318. The second mask material 316 may be formed of and include a dielectric material, such as a dielectric nitride material (e.g., silicide nitride).

The second patterned masking lines 318 may be employed to form the x-axis trenches 304. The x-axis trenches 304 may be formed to terminate (e.g., have lower boundaries) at upper vertical boundaries of the digit line structures 128 (FIG. 2), the projections 212 (FIG. 2) of the shield structure 208, and the second dielectric liner material 202. Accordingly, lower boundaries (e.g., bottoms) of the x-axis trenches 304 may be defined by upper surfaces of the digit line structures 128 (FIG. 2), the projections 212 (FIG. 2) of the shield structure 208, and the second dielectric liner material 202, as depicted in FIG. 5 below. As a result, the semiconductor pillars 319 may be separated from one another by the x-axis trenches 304 and the y-axis trenches 114 (FIG. 2).

As illustrated in FIG. 3A, the x-axis trenches 304 respectively include a termination region 306 within an individual first edge of the array region 108A. The termination region 306 has a second width 310 in the Y-direction that is greater than a first width 308 in the Y-direction of portions of respective ones of the x-axis trenches 304 outside of the first edge of the array region 108A (e.g., within the array region 110). The first edge of the array region 108A is free of the semiconductor pillars 319. The first isolation material 126, but not the semiconductor pillars 319, may be positioned in the spaces between the x-axis trenches 304 in the first edge of the array region 108A.

A pitch 312 between x-axis trenches 304 horizontally neighboring one another in the Y-direction may be substantially constant throughout the memory array structure 102 and the first edge of the array region 108A. In the array region 110, a distance between x-axis trenches 304 horizontally neighboring one another in the Y-direction may be greater than the first width 308 in the Y-direction of respective ones of the x-axis trenches 304, while in the first edge of the array region 108A a distance between the termination regions 306 of x-axis trenches 304 horizontally neighboring one another in the Y-direction may be substantially equal to the second width 310 in the Y-direction of the termination region 306 of respective ones of the x-axis trenches 304. While the distances in the Y-direction between x-axis trenches 304 horizontally neighboring one another in the Y-direction differ based on the width in the Y-direction of the x-axis trenches 304, the pitch 312 between x-axis trenches 304 horizontally neighboring one another in the Y-direction remains substantially constant.

A transition 314 between the first width 308 in the Y-direction of the x-axis trenches 304 and the second width 310 in the Y-direction of the x-axis trenches 304 in the termination region 306 is positioned within the first edge of the array region 108A. Thus, the x-axis trenches 304 enter the first edge of the array region 108A at the first width 308. In the embodiment illustrated in FIG. 3A, the transition 314 is a stepped transition. In other embodiments, the transition 314 may be a gradual transition, such as a graduated transition, an angled transition, or a radiused transition gradually changing from the first width 308 in the Y-direction to the second width 310 in the Y-direction.

As illustrated in FIG. 3A, the memory array structure 102 includes two first edge of the array regions 108A, wherein the two first edge of the array regions 108A are positioned at or proximate opposite lateral ends in the X-direction of the array region 110 than one another. In the embodiment illustrated in FIG. 3A, the first edge of the array regions 108A are enlarged relative to the array region 110 to better illustrate the features and elements of the memory array structure 102 that are different within the first edge of the array regions 108A relative to the array region 110. However, in practice, the array region 110 of the memory array structure 102 is substantially larger than the first edge of the array regions 108A.

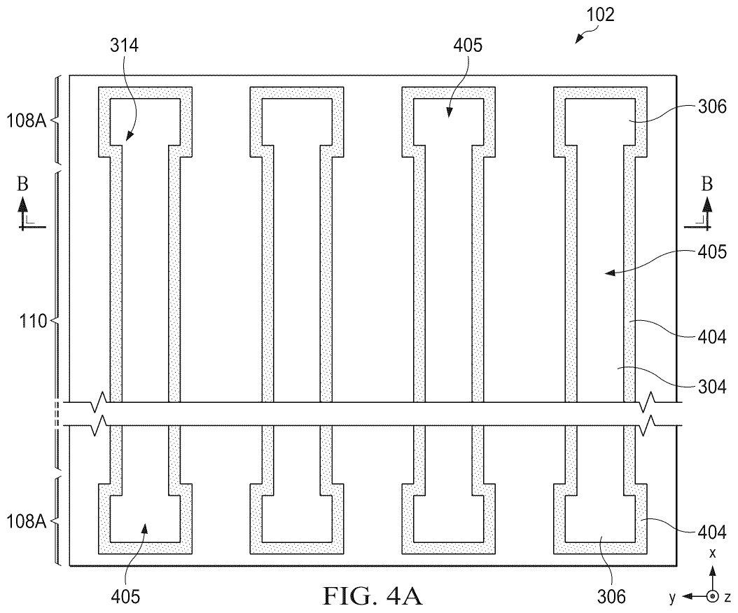

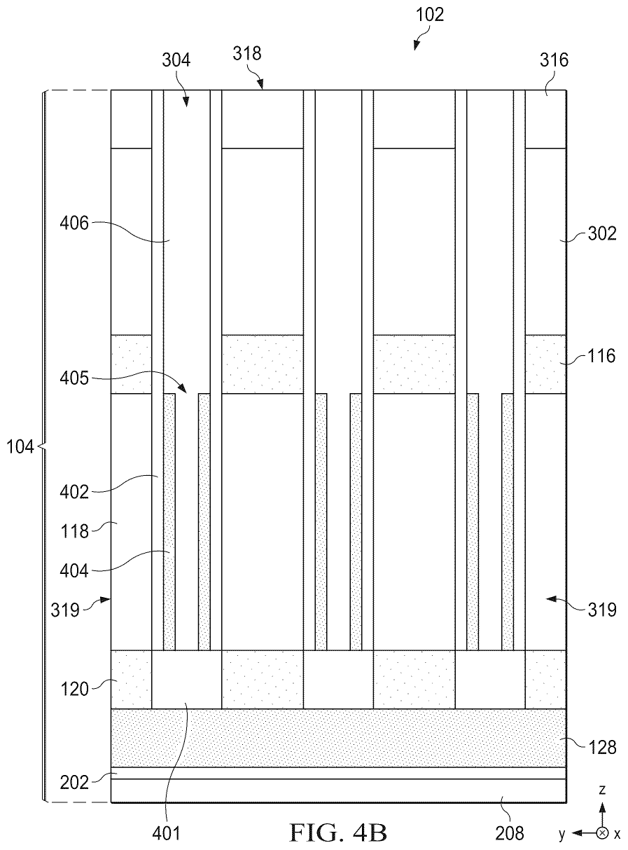

Reference is now collectively made to FIGS. 4A and 4B, which are simplified schematic illustrations of the memory array structure 102 in a subsequent processing step. FIG. 4A illustrates a simplified top-down view of the memory array structure 102, and FIG. 4B illustrates a simplified vertical cross-sectional view of the memory array structure 102 along line B-B.

The x-axis trenches 304 may be partially filled with a spacer material 401. In one or more embodiments, the spacer material 401 is deposited within the x-axis trenches 304 through a spin-on coating process. For instance, the spacer material 401 may include a spin-on dielectric. Furthermore, subsequent to formation, upper portions of the spacer material 401 may be removed (e.g., etched away) to leave only lower portions of the spacer material 401 within lower portions (e.g., bottoms) of the x-axis trenches 304.

In some embodiments, the spacer material 401 is formed of and includes insulative material, such as a dielectric oxide material (e.g., SiOₓ, such as SiO₂). The spacer material 401 may be substantially homogeneous, or the spacer material 401 may be heterogeneous. The spacer material 401 may, for example, be formed of and include a stack of at least two different dielectric materials.

The vertical height (e.g., in the Z-direction) of the remaining portions of the spacer material 401 may serve to position the later-formed gate electrodes (e.g., word lines) a desired distance from the digit line structures 128, the shield structure 208, and a boundary of the second doped region 120 and the undoped region 118 of respective ones of the semiconductor pillars 319. For instance, the remaining portion of the spacer material 401 may space the later-formed gate electrodes (i.e., word line structures (described below)) from the digit line structures 128, the shield structure 208, and a boundary of the second doped region 120 and the undoped region 118 of the respective ones of the semiconductor pillars 319 by desired distances, and as a result, may space the later-formed gate electrodes (i.e., word line structures) from the digit line structures 128. For example, the vertical height of the remaining portions of the spacer material 401 may at least partially determine a distance between the later-formed gate electrodes (i.e., word line structures) and a digit line junction. The remaining portion of the spacer material 401 may exhibit a vertical height within a range of from about 30 nm to about 60 nm. For instance, the spacer material 401 may be etched to have a thickness of about 45 nm.

A third dielectric liner material 402 (i.e., a gate dielectric material) may be formed (e.g., conformally formed) in remaining portions of the x-axis trenches 304, over the semiconductor pillars 319, and over the spacer material 401. The third dielectric liner material 402 may also be referred to as a gate dielectric material. The third dielectric liner material 402 is formed over and along vertical side surfaces of the semiconductor pillars 319 and upper surfaces of the spacer material 401. In some embodiments, bottom portions of the third dielectric liner material 402 are removed by way one or more removal processes such that upper surfaces of the spacer material 401 within the x-axis trenches 304 are partially exposed.

The third dielectric liner material 402 (i.e., gate dielectric material) may be formed of and include insulative material. In some embodiments, the third dielectric liner material 402 is formed of and includes a dielectric oxide material, such as silicon dioxide. In additional embodiments, the third dielectric liner material 402 is formed of and includes a high-k material (a material having a relatively high dielectric constant (k)) as compared to silicon dioxide, such as a dielectric constant greater than about 3.9, greater than or equal to 4, or greater than or equal to 10. In some embodiments, the third dielectric liner material 402 is formed (e.g., conformally deposited) inside and outside of the x-axis trenches 304. The third dielectric liner material 402 may have a thickness within a range of from about 4 nm to about 6 nm (e.g., about 5 nm).

Conductive liner structures 404 may be formed on the second dielectric liner material 202 and within the x-axis trenches 304. The conductive liner structures 404 may include any of the conductive materials described herein.

In one or more embodiments, the conductive liner structures 404 are formed by at least partially filling the x-axis trenches 304 with a gate electrode material, and subsequently removing one or more portions of the gate electrode material. As non-limiting examples, within the x-axis trenches 304, subsequent to depositing the gate electrode material within the x-axis trenches 304, an entirety of the gate electrode material may be recessed down to a desired upper boundary of the conductive liner structure 404, and a center portion of the gate electrode material may be further recessed (e.g., removed) to form recesses 405 extending vertically through the remaining gate electrode material and to the spacer material 401. Within an individual x-axis trench 304, the conductive liner structure 404 extends continuously along all of the sidewalls (e.g., in the X-direction, in the Y-direction) defining the x-axis trench 304. Portions of the conductive liner structure 404 within the array region 110 may horizontally extend substantially linearly in the X-direction. Additional portions of the conductive liner structure 404 within the first edge of the array regions 108A may respectively horizontally extend in a non-linear path that includes sub-portions substantially linearly extending in the X-direction and additional sub-portions substantially linearly extending in the Y-direction. The additional portions of the conductive liner structure 404 within the first edge of the array regions 108A may extend along and follow sidewalls defining the termination regions 306 of the x-axis trenches 304.

The gate electrode material may be formed (e.g., deposited) through any of the manners described herein. Additionally, recessing the gate electrode material and forming the recesses in the gate electrode material may be done by conventional techniques, such as by a directional, selective etch process (e.g., an anisotropic etch process, such as an anisotropic dry or wet etch process) that removes the gate electrode material without significantly removing other exposed materials (e.g., the third dielectric liner material 402 and the spacer material 401) of the first assembly 104.

The recesses 405 may be formed to a desired width (e.g., horizonal dimension) in the Y-direction such that portions of the gate electrode material (and, hence, respective ones of the conductive liner structures 404) remain adjacent to the third dielectric liner material 402 in the Y-direction. In other words, the width of the recesses 405 may be selected to result in a desired horizontal dimensions of the conductive liner structures 404 formed from the gate electrode material. As illustrated in FIG. 4A, the recesses 405 may have a greater width in the Y-direction in the termination region 306 of the associated x-axis trenches 304 than in the array region 110. The width in the Y-direction of the recesses 405 may correspond to the widths 308, 310 in the Y-direction of the x-axis trenches 304, such that the conductive liner structures 404 may respectively have a substantially uniform width in the Y-direction throughout the x-axis trenches 304. Thus, the width in the Y-direction of portions of respective ones of the conductive liner structures 404 may be substantially the same in the termination regions 306 as the width in the Y-direction of additional portions of the respective ones of the conductive liner structures 404 in the array region 110.

The x-axis trenches 304, including the recesses 405 defined by inner side surfaces of the conductive liner structures 404 within the x-axis trenches 304, may individually be filled with a first insulative material 406. The x-axis trenches 304 may individually be filled with the first insulative material 406 up to upper vertical boundaries of the first doped regions 116 of the semiconductor projections 112. The first insulative material 406 may be a spin-on dielectric material, and may be formed by a spin coating process. Moreover, the first insulative material 406 may include any of the dielectric materials described herein. The first insulative material 406 may, optionally, be subjected to an annealing process.

FIG. 5 illustrates a simplified, partial perspective view of a portion of the memory array structure 102 at the processing stage of FIGS. 4A and 4B. As shown in FIG. 5, the semiconductor pillars 319 extend vertically from the digit line structures 128. The x-axis trenches 304 are filled with the spacer material 401 vertically neighboring the digit line structures 128 and positioned between the digit line structures 128 and the third dielectric liner material 402, the conductive liner structures 404, and the first insulative material 406. The third dielectric liner material 402 is formed to laterally neighbor the semiconductor pillars 319 and to be laterally positioned in the Y-direction between the semiconductor pillars 319 and the conductive liner structures 404. The first insulative material 406 fills the respective ones of the recesses 405 defined by the inner side surfaces of respective ones of the conductive liner structures 404 within the x-axis trenches 304, such that horizontally opposing portions of an individual conductive liner structure 404 are laterally separated from one another within the x-axis trenches 304 by the first insulative material 406. The first insulative material 406 may also define an upper boundary of the conductive liner structures 404, such that the conductive liner structures 404 are positioned substantially within a same vertical span of the undoped region 118 of the semiconductor projections 112.

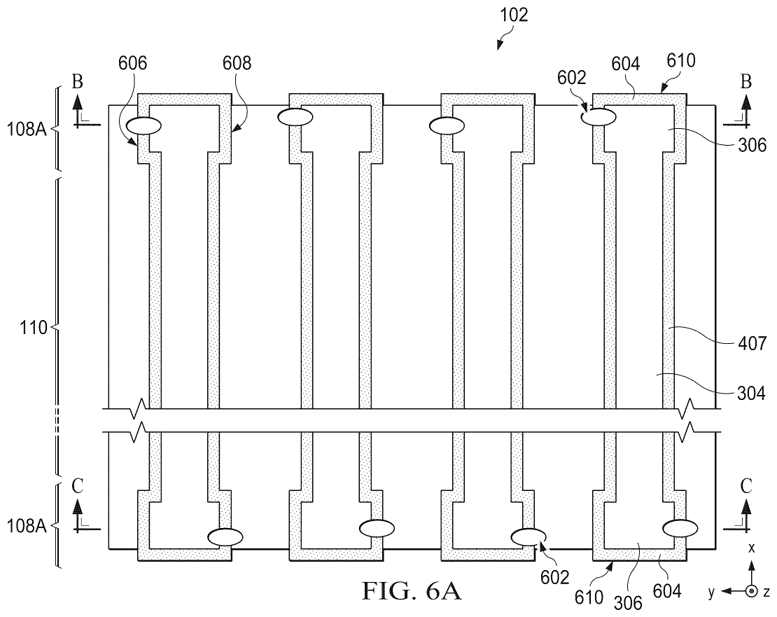

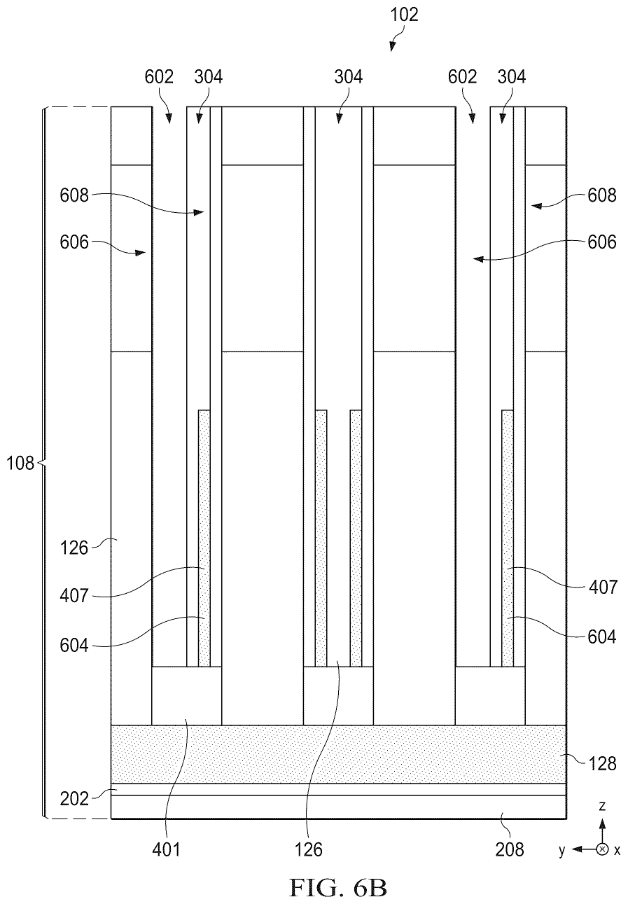

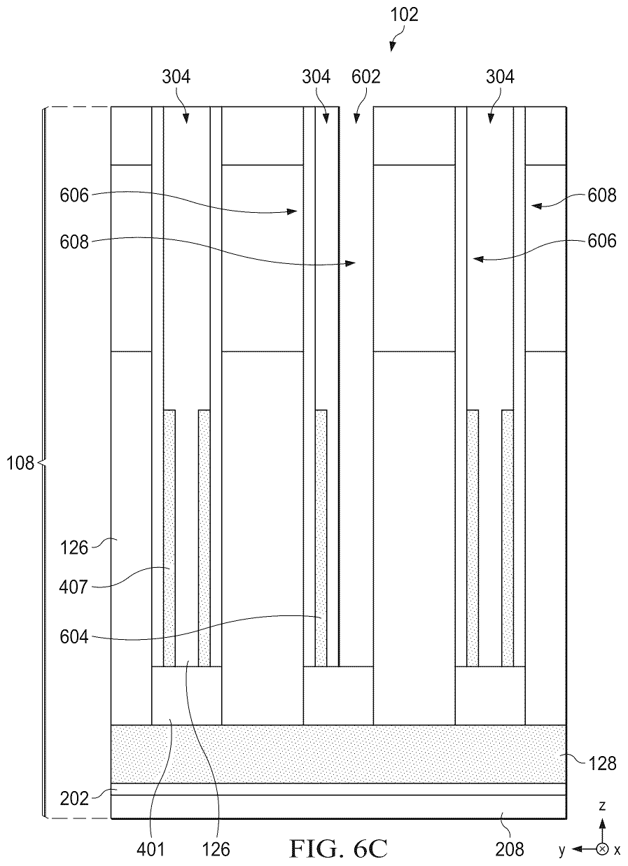

Reference is now collectively made to FIGS. 6A through 6C, which are simplified schematic illustrations of the memory array structure 102 in a subsequent processing step. FIG. 6A illustrates a simplified top-down view of the memory array structure 102; FIG. 6B illustrates a simplified vertical cross-sectional view of the memory array structure 102 along line B-B in FIG. 6A; and FIG. 6C illustrates a simplified vertical cross-sectional view of the memory array structure 102 along line C-C in FIG. 6A. As illustrated in FIG. 6A, the lines B-B and C-C are positioned within the first edge of the array regions 108A that are substantially free of the semiconductor pillars 319.

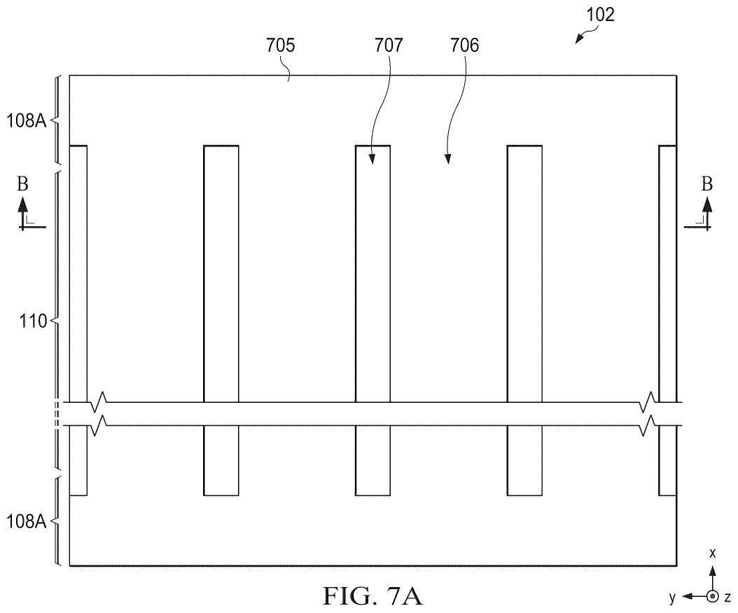

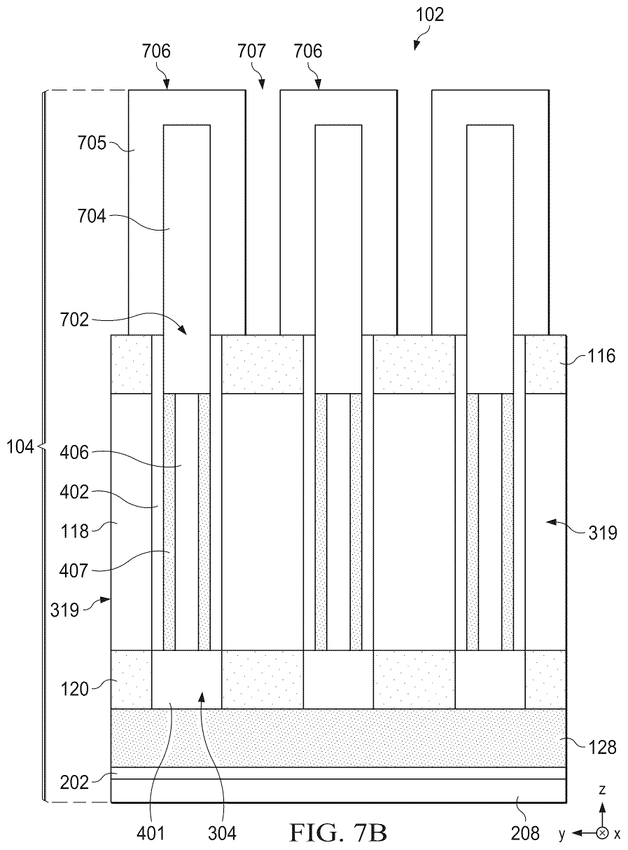

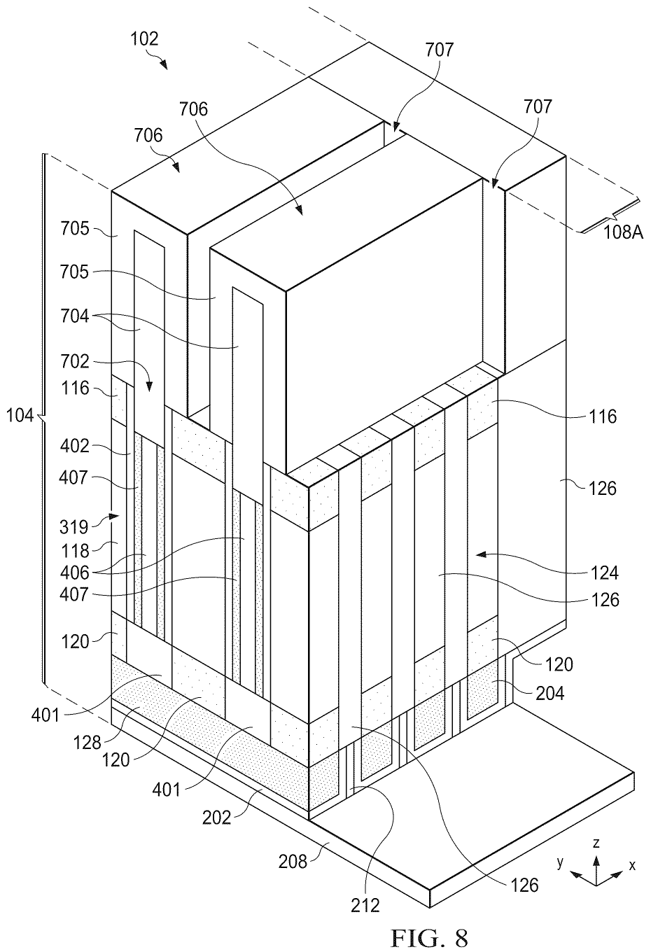

After the x-axis trenches 304 are filled with the spacer material 401, the third dielectric liner material 402, the conductive liner structures 404 (FIG. 4A), and the first insulative material 406, separation recesses 602 are formed to horizontally overlap and vertically extend through portions of respective ones of the conductive liner structures 404 within the termination regions 306 of respective ones of the x-axis trenches 304 to form conductive structures 407 (e.g., word line structures, gate electrodes, gate structures). As illustrated in FIGS. 6B and 6C, the separation recesses 602 individually have a width in the Y-direction that is greater than a width in the Y-direction of the conductive liner structure 404 (FIG. 4A) horizontally overlapped in the Y-direction thereby, and that vertically extends in the Z-direction to a depth greater than a depth of the conductive liner structure 404 (FIG. 4A). Accordingly, portions of an individual the conductive liner structure 404 within the termination regions 306 are entirely removed by the separation recess 602. The separation recesses 602 may vertically extend to or into the spacer material 401 below the conductive structures 407. The separation recess 602 may terminate vertically above the shield structure 208. The separation recesses 602 are configured to electrically isolate the conductive structures 407 positioned within a horizontal area of an individual x-axis trench 304, such that the conductive structures 407 on opposite lateral sides (e.g., in the y-direction) are separate and distinct from one another. Thus, each of the x-axis trenches 304 includes two (2) separate conductive structures 407 configured to operate independently from one another. For an individual x-axis trench 304, the two (2) conductive structures 407 therein may be operatively associated with (e.g., components) different vertical channel access devices (VCADs) of the memory array structure 102 than one another. The formation of the conductive structures 407 may form the VCADs of the memory array structure 102, as described in further detail below with reference to FIG. 7A.

As illustrated in FIG. 6A, one separation recess 602 is positioned at or proximate a first side 606 in the Y-direction of an individual x-axis trench 304 and within one of the two (2) termination regions 306 of the x-axis trench 304, such that the separation recess 602 separates the conductive structures 407 at the first side 606 of the x-axis trench 304. In addition, one other separation recess 602 is positioned in a second side 608 of an individual x-axis trench 304 within one other of the two (2) termination regions 306 of the x-axis trench 304, such that the one other separation recess 602 separates the conductive structures 407 at the second side 608 of the x-axis trench 304. For an individual conductive structure 407, the separation recess 602 defines a termination hook 604 of the conductive structure 407 within one of the two (2) termination regions 306 of the x-axis trench 304. For example, for an individual conductive structure 407, the termination hook 604 may extend along the second side 608 of an individual x-axis trench 304 to a lateral end 610 of the individual x-axis trench 304. The termination hook 604 may then extend horizontally (e.g., in the y-direction) across the lateral end 610 to the first side 606 of the x-axis trench 304 and down the first side 606 of the x-axis trench 304 to the separation recess 602 within the termination region 306. Thus, the termination hook 604 extends the conductive structure 407 across portions of both sides 606, 608 of the x-axis trench 304 within the termination region 306. The termination hook 604 of an individual conductive structure 407 may facilitate a larger area for landing a contact structure on the conductive structure 407, while ensuring the contact structure contacts a single (e.g., only one) conductive structure 407.

As discussed above, the first edge of the array regions 108A at the opposite lateral ends of the memory array structure 102 include additional termination regions 306. As illustrated in FIG. 6A, the separation recesses 602 in the first edge of the array regions 108A on the opposite lateral ends of the memory array structure 102 are on opposite sides 606, 608 of the associated x-axis trenches 304. For example, as discussed above, the separation recesses 602 at the first lateral end of the memory array structure 102 are on the first side 606 of the associated x-axis trenches 304. The separation recesses 602 at the second lateral end of the memory array structure 102 are positioned on the second side 608 of the associated x-axis trenches 304, such that the conductive structures 407 are separated on the second side 608 of the x-axis trenches 304. Thus, the separation recess 602 defines a termination hook 604 in the conductive structure 407 at the first side 606 of the associated x-axis trenches 304. The termination hook 604 extends along the first side 606 of the associated x-axis trenches 304 to the lateral end 610 of the associated x-axis trenches 304. The termination hook 604 then extends horizontally (e.g., in the y-direction) across the lateral end 610 to the second side 608 of the associated x-axis trenches 304 and up the second side 608 of the associated x-axis trenches 304 to the separation recess 602. Thus, the termination hook 604 forms a common conductive structure 407 on both sides 606, 608 of the associated x-axis trenches 304 in the termination region 306. Thus, the termination hook 604 at the first lateral end of the memory array structure 102 may facilitate a larger landing area for the conductive structure 407 that extends along the second side 608 of the x-axis trenches 304 through the array region 110, and the termination hook 604 on the opposite lateral end of the memory array structure 102 may facilitate a larger landing area for the conductive structure 407 that extends along the first side 606 of the x-axis trenches 304 through the array region 110.

As discussed above, each x-axis trench 304 includes two distinct conductive structures 407 extending along opposing lateral sides of the respective x-axis trench 304. Each x-axis trench 304 includes two termination regions 306 on opposing lateral ends of the x-axis trench 304 where the x-axis trenches are wider. A first conductive structure 407 of the two distinct conductive structures 407 includes the termination hook 604 defined in the termination region 306 of the x-axis trench 304 on a first lateral end of the x-axis trench 304. The first conductive structure 407 follows a substantially rectangular path around the termination region 306 of the x-axis trench to the separation recess 602. The substantially rectangular path has a hook or “J” shape, where the path of the first conductive structure 407 includes two connected or continuous portions that are parallel to one another on the first side 606 and the second side 608 of the termination region 306 of the x-axis trench. A second of the two distinct conductive structures 407 includes a termination hook 604 having substantially the same shape and path of the first conductive structure 407 that extends into the termination region 306 of the x-axis trench 304 on the second lateral end of the x-axis trench 304 opposite the first lateral end of the x-axis trench 304.

In the embodiment illustrated in FIG. 6A, the lateral positions of the separation recesses 602 are staggered, such that the separation recesses 602 in horizontally neighboring (e.g., in the Y-direction) x-axis trenches 304 are not positioned at a same lateral distance (e.g., in the X-direction) from the lateral end 610 of the respective x-axis trenches 304. Thus, in the vertical cross-section taken along line B-B, illustrated in FIG. 6B, a separation recess 602 is not shown in one of the x-axis trenches 304. The x-axis trench 304 that does not include a depicted separation recess 602 (the separation recess 602 is outside of the depicted ZY-plane) neighbors each of the x-axis trenches 304 that include a depicted separation recess 602. Similarly, in the cross-section taken along line C-C, illustrated in FIG. 6C, one of the x-axis trenches 304 includes a depicted separation recess 602 whereas the others do not (the separation recesses 602 are outside of the depicted ZY-plane).

The separation recesses 602 are filled with an insulative material in a subsequent process. The insulative material in the separation recesses 602 is configured to provide electrical isolation of the conductive structures 407 on either side (e.g., in the X-direction) of the separation recesses 602 as discussed above.

Reference is now collectively made FIGS. 7A through 8, which are simplified schematic illustrations of the memory array structure 102 in a subsequent processing step. FIG. 7A illustrates a simplified top-down view of the memory array structure 102; FIG. 7B illustrates a simplified vertical cross-sectional view of the memory array structure 102 along line B-B of FIG. 7A; and FIG. 8 illustrates a perspective sectional view of a portion of the memory array structure 102 at the processing stage of FIGS. 7A and 7B.

Portions (e.g., upper portions) of the first insulative material 406 within horizontal areas of the x-axis trenches 304 are removed. Upper boundaries of remaining portions of the first insulative material 406 may be within a vertical span of the semiconductor pillars 319. For example, upper boundaries of remaining portions of the first insulative material 406 be within the vertical span of the first doped region 116 of respective ones of the semiconductor pillars 319. The removed portions of the first insulative material 406 form recesses 702 having lower boundaries defined by the remaining portions of the first insulative material 406. An individual recess 702 may vertically terminate above upper surfaces of the conductive structures 407. The recesses 702 may have horizontal dimensions (e.g., in the X-direction, in the Y-direction) less than horizontal dimensions (e.g., in the X-direction, in the Y-direction) of the associated x-axis trenches 304. The third dielectric liner material 402 (e.g., the gate dielectric material) may remain following the formation of the recesses 702.

After formation, the recesses 702 are respectively filled with a third mask material 704. The third dielectric liner material 402 may be positioned between the third mask material 704 and the semiconductor pillars 319. The third mask material 704 may be formed of and include dielectric material having a different material composition than those of the first insulative material 406 and the third dielectric liner material 402. For example, the third mask material 704 may be formed of and include low-k dielectric material (e.g., silicon oxycarbide). The third mask material 704 may be selected to have different etching characteristics than the first insulative material 406 and the semiconductor pillars 319. In some embodiments, the third mask material 704 is formed of and includes dielectric nitride material (e.g., silicide nitride).

The second mask material 316 (FIG. 4B) and the sacrificial structure 302 (FIG. 4B) may be removed (e.g., through an etching process, such as a dry etching process or a wet etching process), and spacer material 705 may be formed on exposed surfaces (e.g., sidewalls, upper surfaces) of the third mask material 704. In some embodiments, the spacer material 705 is formed inside and outside of openings (e.g., trenches, spaces, voids) between neighboring portions of the third mask material 704 and over remaining portions of the first insulative material 406 created by removal of the second mask material 316, and then portions (e.g., center portions) thereof within horizonal areas of the openings are removed through one or more etching processes. The spacer material 705 may be formed of and include dielectric material, such as one or more of dielectric oxycarbide material (e.g., silicon oxycarbide) and dielectric nitride material (e.g., silicon nitride).

As discussed above, the termination regions 306 (FIG. 4A) of the x-axis trenches 304 within the first edge of the array regions 108A are relatively wider in the Y-direction than other portions (e.g., middle portions) of the x-axis trenches 304 within the array region 110. The wider termination regions 306 may result in portions of the spacer material 705 within horizontal areas of the first edge of the array regions 108A substantially continuously horizontally extending across and covering the horizontal areas of the edge of the array regions 108, while other portions of the portions of the spacer material 705 within the array region 110 are segmented. In the embodiment illustrated in FIG. 7A, the spacer material 705 covers the entireties of the horizontal areas of the first edge of the array regions 108A.

Together, the third mask material 704 and the spacer material 705 may form third patterned masking lines 706 horizontally extending in parallel with one another in the X-direction. Openings 707 may be defined between neighboring (in the Y-direction) third patterned masking lines 706, and may expose upper surfaces of the first doped regions 116 and the first isolation material 126. In the embodiment illustrated in FIG. 7A, the openings 707 do not horizontally extend completely through the first edge of the array regions 108A. As discussed above, the width of the termination regions 306 (FIG. 4A) of the x-axis trenches 304 causes the spacer material 705 to substantially cover entireties of the first edge of the array regions 108A. Thus, the openings 707 at or proximate to the termination regions 306 (FIG. 4A) of the x-axis trenches 304. In some embodiments, the openings 707 extend a small distance into the first edge of the array regions 108A before terminating, such as a distance within a range of from about 5 nm to about 30 nm. In other embodiments, the openings 707 may terminate before entering the first edge of the array regions 108A. For example, the openings 707 may terminate at the boundary between the array region 110 and the first edge of the array regions 108A.

Reference is now collectively made to FIGS. 9A and 9B, which are simplified schematic illustrations of the memory array structure 102 in a subsequent processing step. FIG. 9A illustrates a simplified top-down view of the memory array structure 102 and FIG. 9B illustrates a simplified vertical cross-sectional view of the memory array structure 102 along line B-B.

As illustrated in FIG. 9A, a mask 901 may be provided over the first edge of the array regions 108A. The mask 901 may be one or more of a photoresist mask and a hard mask configured to substantially protect the first edge of the array regions 108A thereunder from an etching process. For example, the mask 901 may be configured to prevent the removal of material vertically underlying and horizontally covered thereby.

Portions of the third patterned masking lines 706 and the openings 707 defined thereby remaining uncovered by the mask 901 may be employed to form second x-axis trenches 902 extending vertically into the first assembly 104. The second x-axis trenches 902 extend horizontally in parallel in the X-direction. The second x-axis trenches 902 extend vertically into the first assembly 104 to an elevation (e.g., vertical level) at least substantially coplanar with upper surfaces of the digit line structures 128 (FIG. 8) and projections 212 (FIG. 8) of the shield structure 208. Thus, the second x-axis trenches 902 extend vertically through the semiconductor pillars 319 (FIGS. 7B and 8) to form additional semiconductor pillars 904 therefrom. Each of the additional semiconductor pillars 904 may respectively include the first doped region 116, the undoped region 118, and the second doped region 120 of semiconductor material. Accordingly, lower boundaries (e.g., bottoms) of the second x-axis trenches 902 may be defined by exposed upper surfaces of the digit line structures 128 (FIG. 8), the projections 212 (FIG. 8) of the shield structure 208, and the second dielectric liner material 202.

The second x-axis trenches 902 may respectively terminate, in the X-direction, at or proximate the horizonal boundaries of first edge of the array region 108A. As illustrated in FIG. 9A, the mask 901 is utilized during formation of the second x-axis trenches 902 to define the horizontal boundaries of the second x-axis trenches 902 in the X-direction. In particular, horizontal boundaries of each of the second x-axis trenches 902 in the X-direction may horizontally overlap horizontal boundaries of the first edge of the array regions 108A. As a result, horizontal boundaries of each of the second x-axis trenches 902 in the X-direction may be defined by vertical sidewalls of remaining portions of the first isolation material 126 within the first edge of the array regions 108A.

The formation of the second x-axis trenches 902 and the additional semiconductor pillars 904 effectuates the formation of vertical channel access devices (VCADs) 214 within the array region 110 of the memory array structure 102. The additional semiconductor pillars 904 (including the first doped regions 116, the undoped regions 118, and the second doped regions 120 thereof), the third dielectric liner material 402, and the conductive structures 407 may together form the vertical channel access devices 214. The vertical channel access devices 214 may individually include a channel region comprising the undoped region 118 of an individual additional semiconductor pillar 904, a drain region comprising the first doped region 116 of the additional semiconductor pillar 904, and a source region comprising the second doped region 120 of the additional semiconductor pillar 904. In addition, the vertical channel access device 214 may include a gate electrode comprising a portion of an individual conductive structure 407 and a gate dielectric material comprising the third dielectric liner material 402. Different portions of an individual conductive structure 407 form gates for multiple vertical channel access devices 214.

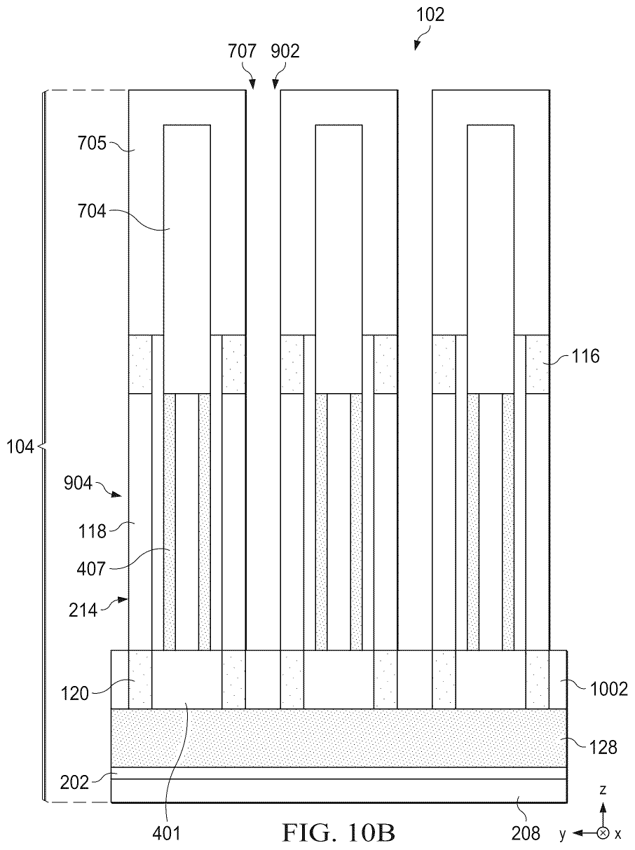

Reference is now collectively made to FIGS. 10A and 10B, which are simplified schematic illustrations of the memory array structure 102 in a subsequent processing step. FIG. 10A illustrates a simplified top-down view of the memory array structure 102 and FIG. 10B illustrates a simplified vertical cross-sectional view of the memory array structure 102 along line B-B.

After the second x-axis trenches 902 are formed, spacer structures 1002 are formed in the second x-axis trenches 902. The second x-axis trenches 902 may be partially filled within the spacer structures 1002. In one or more embodiments, the spacer structures 1002 are formed within the second x-axis trenches 902 through a spin-on coating process followed by an etching process. The spacer structures 1002 respectively may be formed to a vertical height above the vertical boundary of the second doped regions 120 of the additional semiconductor pillars 904.

The spacer structures 1002 are formed of and include insulative material, such as a dielectric material. In some embodiments, the spacer structures 1002 is formed of and includes a dielectric oxide material, such as SiOₓ (e.g., SiO₂). The spacer structure 1002 may be substantially homogeneous, or the spacer structure 1002 may be heterogeneous. The spacer structure 1002 may, for example, be formed of and include a stack of at least two different dielectric materials.

The vertical height of the spacer structures 1002 may serve to position the later-formed shield gates (e.g., shield word lines) a desired vertical distance (e.g., in the Z-direction) from the digit line structures 128 (FIG. 2) and a boundary of the second doped region 120 and the undoped region 118 of the additional semiconductor pillars 904. For instance, the spacer structures 1002 may space the later-formed shield gates from the digit line structures 128 (FIG. 2) and a boundary of the second doped region 120 and the undoped region 118 of respective ones of the additional semiconductor pillars 904 by a desired vertical distance, and as a result, may space the later-formed shield gates from the digit line structures 128. The spacer structures 1002 may exhibit a vertical thickness within a range of from about 30 nm to about 60 nm. For instance, the spacer structures 1002 may have a thickness of about 45 nm.

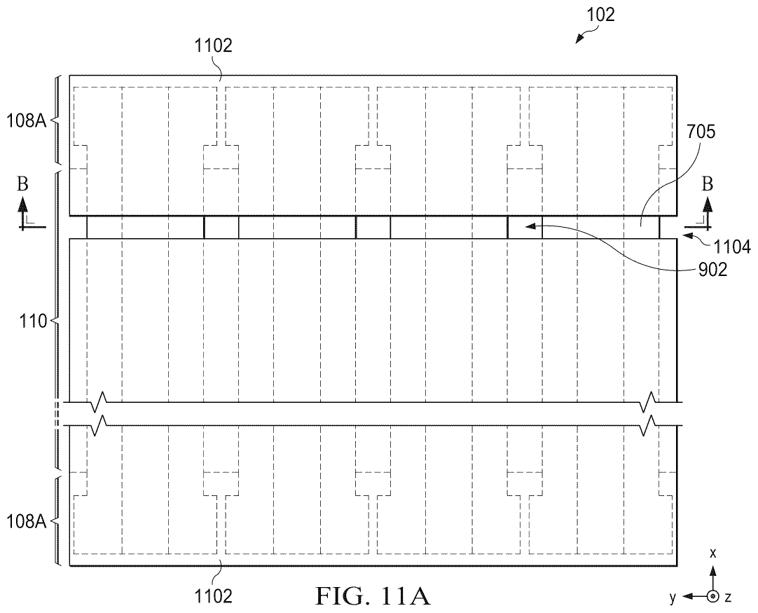

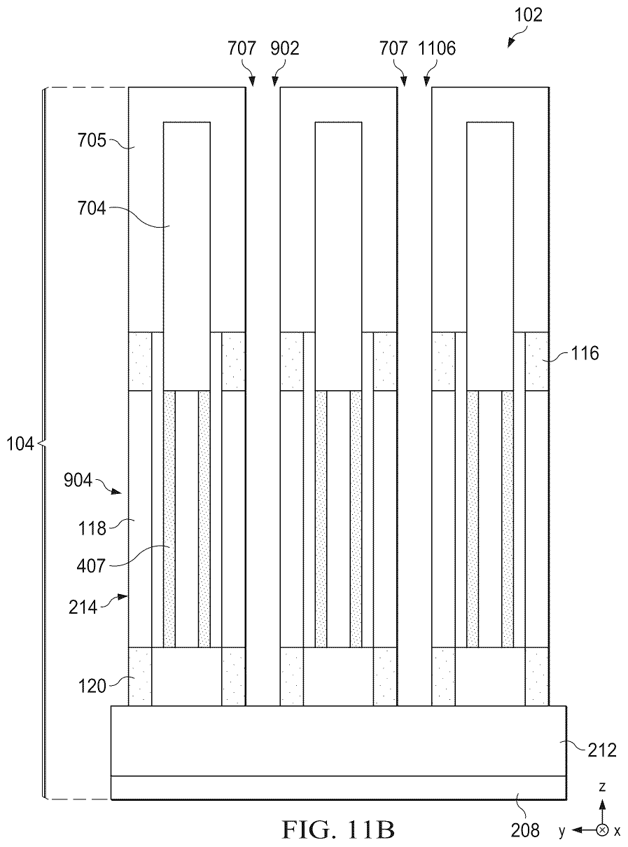

Reference is now collectively made to FIGS. 11A and 11B, which are simplified schematic illustrations of the memory array structure 102 in a subsequent processing step. FIG. 11A illustrates a simplified top-down view of the memory array structure 102 and FIG. 11B illustrates a simplified vertical cross-sectional view of the memory array structure 102 along line B-B.

As illustrated in FIG. 11A, an additional mask 1102 is positioned over the memory array structure 102. The additional mask 1102 may be one or more of a photoresist mask and a hard mask configured to substantially protect the horizontal areas thereunder from additional etching process. The additional mask 1102 may be configured to prevent the removal of material vertically underlying and horizontally covered thereby.

The additional mask 1102 defines open regions 1104 (e.g., open areas) within the array region 110. The open regions 1104 may respectively be positioned to vertically overlie and horizontally overlap (e.g., in the X-direction) one of the y-axis trenches 114 (FIG. 1). An individual open region 1104 extends in the Y-direction and does not horizontally overlap any of the digit line structures 128 in the X-direction.

As illustrated in FIG. 11B, portions of the spacer structures 1002 are removed from the second x-axis trenches 902 through the openings 707 in the spacer material 705 exposed by the open regions 1104 of the mask 1102. The portions of the spacer structures 1002 are removed to form slots 1106 within horizontal areas of portions of the second x-axis trenches 902 defined by the open regions 1104 of the mask 1102. Lower boundaries (e.g., bottoms) of the slots 1106 may be defined by exposed upper surfaces of the projections 212 of the shield structure 208 and the second dielectric liner material 202 (FIG. 8). Additional portions of the spacer structures 1002 remain in the other regions of the second x-axis trenches 902 protected by the additional mask 1102.

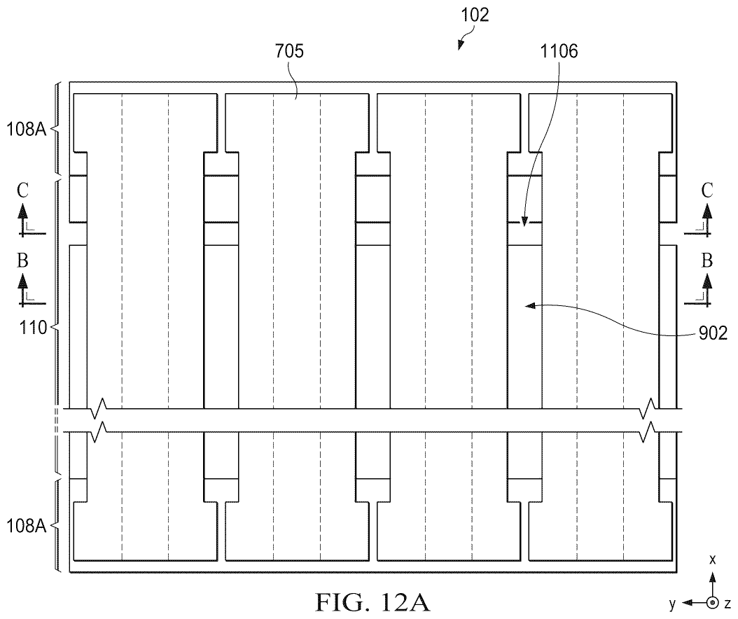

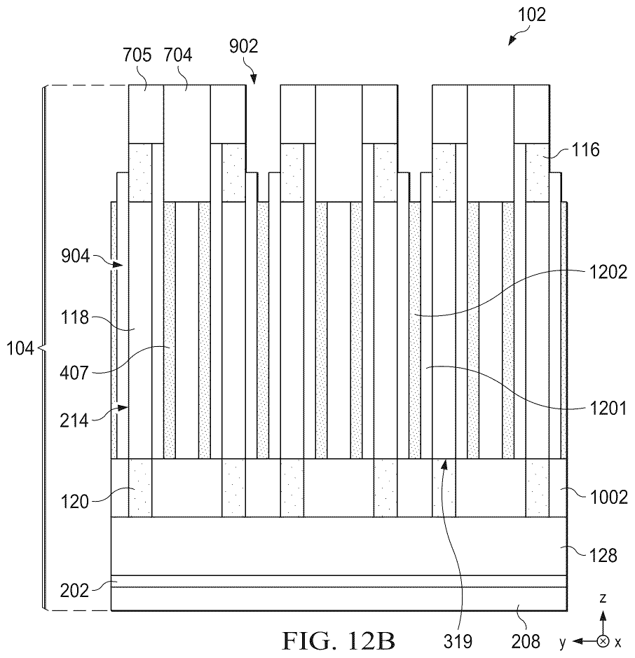

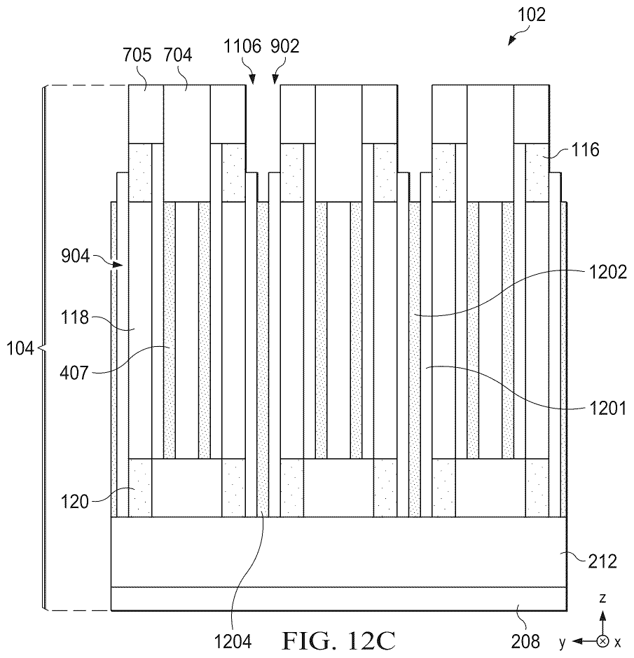

Reference is now collectively made to FIGS. 12A through 12C, which are simplified schematic illustrations of the memory array structure 102 in a subsequent processing step. FIG. 12A illustrates a simplified top-down view of the memory array structure 102; FIG. 12B illustrates a simplified vertical cross-sectional view of the memory array structure 102 along line B-B; and FIG. 12C illustrates a simplified vertical cross-sectional view of the memory array structure 102 along line C-C. The lines B-B and C-C each extend through the array region 110 of the memory array structure 102 intersecting the second x-axis trenches 902. The line C-C extends through the slots 1106 formed in the processing stage described above with reference to FIGS. 11A and 11B.

A fourth dielectric liner material 1201 (e.g., a gate dielectric material) may be formed in the second x-axis trenches 902. In some embodiments, the fourth dielectric liner material 1201 is conformally deposited inside the second x-axis trenches 902. The fourth dielectric liner material 1201 may be formed over and along vertical sidewalls of the spacer material 705, over exposed vertical sidewalls of the additional semiconductor pillars 904, over exposed upper surfaces of the spacer structure 1002, and over exposed surfaces of the projections 212 of the shield structure 208. The fourth dielectric liner material 1201 may also be referred to as a gate dielectric material. In some embodiments, the fourth dielectric liner material 1201 is formed to substantially completely cover the upper surfaces of the spacer structures 1002. In other embodiments, such as the embodiment illustrated in FIG. 12B, portions of the fourth dielectric liner material 1201 are removed from the upper surfaces of the spacer structures 1002, such that the upper surfaces of the spacer structures 1002 form portions of a lower boundary of the second x-axis trenches 902 (and of portions of shield gates 1202 formed within remainders of the second x-axis trenches 902, as described in further detail below).

The fourth dielectric liner material 1201 may be formed of and include insulative material. In some embodiments, the fourth dielectric liner material 1201 is formed of and includes silicon dioxide. In additional embodiments, the fourth dielectric liner material 1201 is formed of and includes a high-k dielectric material. The fourth dielectric liner material 1201 may have a thickness within a range of from about 4 nm to about 6 nm (e.g., about 5 nm).

Shield gates 1202 may be formed on the fourth dielectric liner material 1201 and within horizontal areas of the second x-axis trenches 902. The shield gates 1202 may include any of the conductive materials described herein. In one or more embodiments, the shield gates 1202 are formed by at least partially filling the second x-axis trenches 902 with a gate electrode material, and subsequently removing one or more portions of the gate electrode material. As non-limiting examples, within the second x-axis trenches 902, subsequent to depositing the gate electrode material within the second x-axis trenches 902, an entirety of the gate electrode material may be recessed down to a desired upper boundary of the shield gates 1202, and the remaining gate electrode material within each second x-axis trench 902 forms a given shield gate 1202.

The shield gates 1202 may be formed (e.g., deposited) through any of the manners described herein. Additionally, recessing the gate electrode material and forming the recesses in the gate electrode material may be done by conventional techniques, such as by a directional, selective etch process (e.g., an anisotropic etch process, such as an anisotropic dry or wet etch process) that removes the gate electrode material without significantly removing other exposed materials (e.g., the fourth dielectric liner material 1201) of the first assembly 104.

The upper boundaries of the shield gates 1202 may be positioned within a vertical span of the additional semiconductor pillars 904. For example, the upper boundaries of the shield gates 1202 may be positioned between the upper boundaries of the second doped regions 120 of the additional semiconductor pillars 904 and the upper boundaries of the first doped regions 116 of the additional semiconductor pillars 904. In some embodiments, the upper boundaries of the shield gates 1202 substantially vertically align with the upper boundaries of the undoped regions 118 of the additional semiconductor pillars 904. In additional embodiments, the upper boundaries of the shield gates 1202 are positioned within the vertical span of the undoped regions 118 of the additional semiconductor pillars 904, such that the upper boundaries of the shield gates 1202 are vertically between the lower boundaries of the undoped regions 118 of the additional semiconductor pillars 904 and the upper boundaries of the undoped regions 118 of the additional semiconductor pillars 904.

As illustrated in FIG. 12C, the shield gates 1202 extend into the slots 1106 formed through the spacer structures 1002 in the process described above, with respect to FIGS. 11A and 11B. As noted above, the slots 1106 are positioned in one of the y-axis trenches 114 (FIG. 1), such that downwardly projecting portions 1204 of the shield gates 1202 extending into the slots 1106 do not horizontally overlap any of the digit line structures 128 in the X-direction. The downwardly projecting portions 1204 of the shield gates 1202 may respectively be horizontally interposed, in the X-direction, between two (2) of the digit line structures 128 horizontally neighboring one another in the X-direction. The downwardly projecting portions 1204 of the shield gates 1202 may vertically extend through the spacer structures 1002 (FIG. 12B) to the projections 212 of the shield structure 208. Accordingly, lower boundaries (e.g., bottoms) of downwardly projecting portions 1204 of the shield gates 1202 in the slots 1106 may be defined by the upper surfaces of the projections 212 of the shield structure 208, and the second dielectric liner material 202 (FIG. 8). Thus, the shield gates 1202 may be in electrical contact with the projections 212 of the shield structure 208. The projections 212 and the shield structure 208 may provide a ground to the shield gates 1202 within the array region 110 of the memory array structure 102 through the slots 1106.

In some embodiments, the lower boundaries of the shield gates 1202 are formed by the fourth dielectric liner material 1201. A ground contact may be formed in a subsequent process by removing material from the opposite side of the memory array structure through the shield structure 208 and the fourth dielectric liner material 1201 and forming an external ground contact with the shield gates 1202 at the slots 1106. In other embodiments, the fourth dielectric liner material 1201 may be removed along with any other insulative material (e.g., the second dielectric liner material 202) between the bottom of the slots 1106 and the projections 212 of the shield structure 208, such that the downwardly projecting portions 1204 of the shield gates 1202 extending into the slots 1106 are formed in direct contact with upper surfaces of the projections 212 of the shield structures 208 that horizontally overlap the slots 1106.

Reference is now collectively made to FIGS. 13A and 13B, which are simplified schematic illustrations of the memory array structure 102 in a subsequent processing step. FIG. 13A illustrates a simplified vertical cross-sectional view of the memory array structure 102 of FIG. 12A in a subsequent processing step along line B-B. FIG. 13B illustrates a simplified vertical cross-sectional view of the memory array structure 102 of FIG. 12A in a subsequent processing step along line C-C. As discussed above, the lines B-B and C-C each extend through the array region 110 of the memory array structure 102 intersecting the second x-axis trenches 902. The line C-C extends through the horizontal areas of the slots 1106 formed in the processing stage described above with reference to FIGS. 11A and 11B.

Any unfilled portions of the second x-axis trenches 902 above the shield gates 1202 may be filled with a second insulative material 1302. The second x-axis trenches 902 may be filled with the second insulative material 1302 up to upper vertical boundaries of the third mask material 704. The second insulative material 1302 may be a spin-on dielectric material, and may be formed by a spin coating process. Moreover, the second insulative material 1302 may include any of the dielectric materials described herein. The second insulative material 1302 may optionally be subjected to an annealing process.

The shield gates 1202 within the second x-axis trenches 902 may form shield gates 1202 that shield conductive structures 407 from cross-interference between conductive structures 407. For example, the shield gates 1202 may control electrical field interference between vertical channel access devices 214 (e.g., vertical transistors, access transistors) that include the additional semiconductor pillars 904. In some embodiments, the shield gates 1202 are formed from tungsten or another conductive material. In one or more embodiments, the shield gates 1202 are formed from a semiconductor material (e.g., polysilicon). Furthermore, as described above, the shield gates 1202 may be operably connected to a ground of a respective voltage supply through the projections 212 of the shield structure 208 and the portions of the shield gates 1202 that extend into the slots 1106.

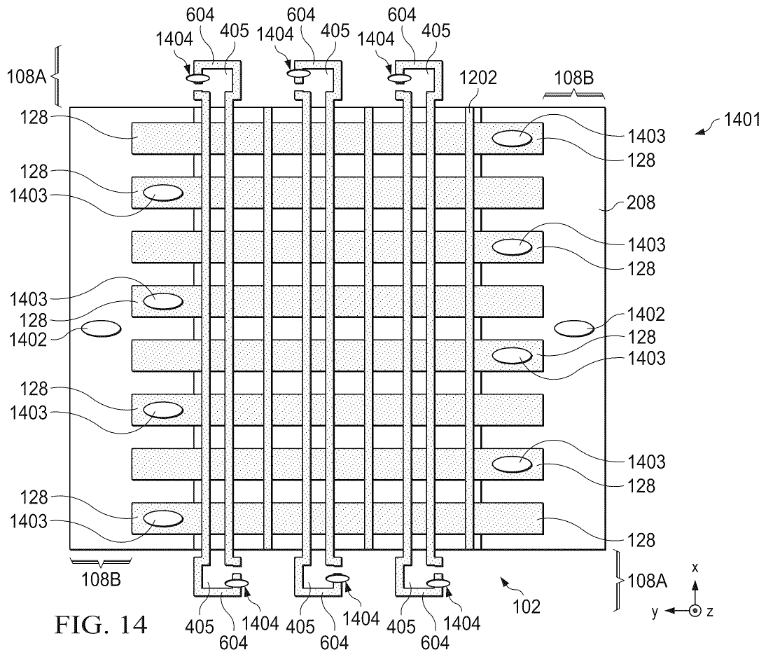

FIG. 14 is a simplified, schematic, top-down view of a microelectronic device 1401 including at least one first assembly 104 including a memory array structure 102 vertically overlying a shield structure 208. FIG. 14 illustrates features from multiple different vertical planes overlaid to illustrate the lateral relationship between the features. Not every element of the first assembly 104 is depicted within FIG. 14 for clarity and ease of depiction, and the first assembly 104 may include any of the materials, structures, and elements (e.g., dielectric materials, dielectric liner materials, structures, etc.) previously described herein with reference to one or more of FIGS. 1 through 13B.

The microelectronic device 1401 illustrated in FIG. 14, is formed by inverting the first assembly 104 and attaching (e.g., bonding, such as dielectric-to-dielectric bonding, metal-to-metal bonding) the first assembly 104 to a second assembly, such as peripheral circuitry assembly including control logic circuitry and power management circuitry. As discussed above, in some embodiments, the digit line structures 128, the additional y-axis trenches 130 (FIG. 1), the second dielectric liner material 202, and the shield structure 208 (including the projections 212 thereof) are formed after the processing stage described herein with reference to FIG. 13B, and before bonding the first assembly 104 to the second assembly. For example, the processing discussed above, with respect to FIGS. 1 and 2 may be performed after inverting the first assembly 104 of FIG. 13B. Contact structures are subsequently formed between structures in the first assembly 104 and features (e.g., structures, materials, devices) of the second assembly. The contact structures may be configured to electrically connect features of the first assembly 104 to features of the second assembly. Thus, during use and operation of the microelectronic device 1401, the contact structures may facilitate the transmission of data and signals between the features the first assembly 104 and the features of the second assembly.

As is shown in FIG. 14, and as described above, the first assembly 104 may include the shield structure 208, conductive structures 407 extending in the X-direction and through the memory array structure 102, shield gates 1202 extending in the X-direction and through the memory array structure 102, and digit line structures 128 extending in the Y-direction and through the memory array structure 102. Furthermore, edge of the array regions 108A, 108B may be defined at opposing sides of the memory array structure 102 (e.g., at or proximate horizontal edges of a patch region of the microelectronic device 1401) in both the X-direction and the Y-direction.

As described above, the shield gates 1202 may be operably coupled to the shield structure 208. Shield contacts 1402 of the shield structure 208 of the first assembly 104 may be formed and located at or proximate horizontal edges of the first assembly 104 and within second edge of the array regions 108B. In other words, the shield contacts 1402 of the shield structures 208 may be formed proximate horizontal perimeters of the first assembly 104. As noted above, the shield contacts 1402 may be utilized to bias the shield structure 208 with a voltage to control or enhance protection provided by the shield structure 208 from undesirable electrical interference (e.g., electromagnetic interference (EMI)). In some embodiments, the shield contacts 1402 of the first assembly 104 are formed within the second edge of the array regions 108B proximate digit line exit regions of the first assembly 104. In other embodiments, the shield contacts 1402 of the first assembly 104 are formed within the first edge of the array regions 108A opposite digit line exit regions of the first assembly 104.

Digit line contacts 1403 of the first assembly 104 may be formed and located at or proximate horizontal edges of the first assembly 104, within the second edge of the array regions 108B, and within digit line contact socket regions of the first assembly 104. In other words, the digit line contacts 1403 may be formed proximate horizontal perimeters of the first assembly 104. The digit line contacts 1403 may be formed to contact (e.g., physically contact, electrically contact) respective digit line structures 128 and to couple the digit line structures 128 to other circuitry (e.g., sense amplifiers (e.g., equalization (EQ) amplifiers, isolation (ISO) amplifiers, NMOS sense amplifiers (NSAs), PMOS sense amplifiers (PSAs)), read buffers, decoders (e.g., local deck decoders, column decoders, row decoders), pre-charge circuits, and drivers (e.g., main digit line drivers, sub digit line drivers)) of the microelectronic device 1401.

As discussed above, the conductive structures 407 extend laterally in the X-direction through the memory array structure 102. The conductive structures 407 define termination hooks 604 in the first edge of the array regions 108A at or proximate opposing lateral ends of the memory array structure 102 in the X-direction. Word line contacts 1404 of the first assembly 104 may be formed and located at or proximate horizontal edges of the first assembly 104, within the first edge of the array regions 108A, and within the termination hooks 604 of conductive structures 407 of the first assembly 104. The word line contacts 1404 may be formed to contact (e.g., physically contact, electrically contact) respective termination hooks 604 of the conductive structures 407 and to couple the conductive structures 407 to other circuitry (e.g., charge pumps (e.g., V_{CCP} charge pumps, V_{NEGWL} charge pumps, DVC2 charge pumps), drivers (e.g., main word line drivers, sub word line drivers (SWD)), decoders (e.g., local deck decoders, column decoders, row decoders), repair circuitry (e.g., column repair circuitry, row repair circuitry), and memory test devices) of the microelectronic device 1401. In some embodiments, the word line contacts 1404 are part of contact assemblies coupled to a cell plate and connecting various structures vertically throughout the microelectronic device 1401.

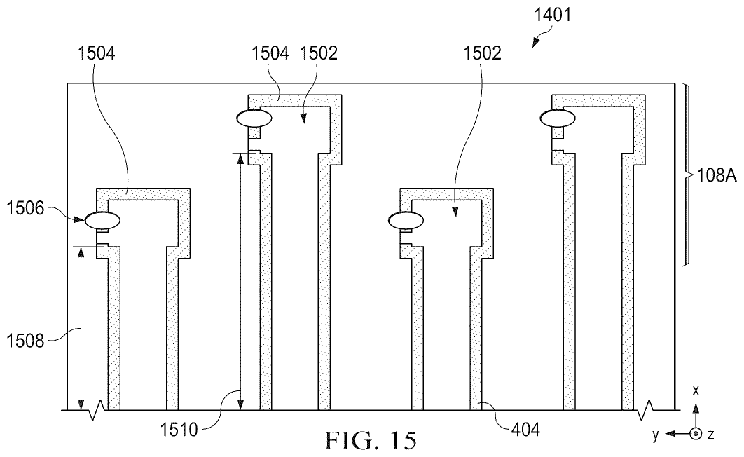

FIG. 15 illustrates an embodiment of one of the first edge of the array regions 108A of the memory array structure 102 with a staggered arrangement of terminal ends of the conductive structures 407 therein. In the embodiment illustrated in FIG. 15, the conductive structures 407 respectively include a termination region 1502 with a width in the Y-direction greater than the distance in the Y-direction between the conductive structures 407 in the array region 110 of the memory array structure 102 similar to the termination regions 306 (FIG. 3A) described above. The termination regions 1502 of the embodiment illustrated in FIG. 15 are staggered laterally (e.g., in the X-direction), such that the termination regions 1502 of neighboring conductive structures 407 are positioned different distances 1508, 1510 in the X-direction from the array region 110.

As illustrated in FIG. 15, a first of the termination regions 1502 is positioned a first distance 1508 in the X-direction from the array region 110 and a second of the termination regions 1502 horizontally neighboring the first of the termination regions 1502 in the Y-direction is positioned a second distance 1510 in the X-direction from the array region 110. The second distance 1510 is greater than the first distance 1508. The first of the termination regions 1502 may be sized and arranged such that that the conductive structure 407 formed along vertical sidewalls of the first termination region 1502 forms a termination hook 1504 extending laterally in the X-direction along a first side of the first termination region 1502 across the first termination region in the Y-direction and returning in the X-direction along a second side of the first termination region 1502. The conductive structure 407 in the first termination region 1502 may cross in the Y-direction and return in the X-direction before the conductive structure 407 in the first termination region 1502 reaches the second distance 1510. Thus, the first of the termination regions 1502 and the second of the termination regions 1502 do not laterally overlap one another in the X-direction or the Y-direction.

The staggered arrangement of the termination regions 1502 may result in increased space for word line contacts 1506 to land while only contacting one conductive structure 407. For example, as discussed above, the termination hooks 1504 of the conductive structures 407 may individually create an increased area where the word line contacts 1506 can land without contacting the other conductive structure 407 in the same termination region 1502. The staggered arrangement of the termination regions 1502 may also increase the area around the termination regions 1502 where the word line contacts 1506 can land without contacting the conductive structures 407 in a neighboring x-axis trench or termination region 1502.

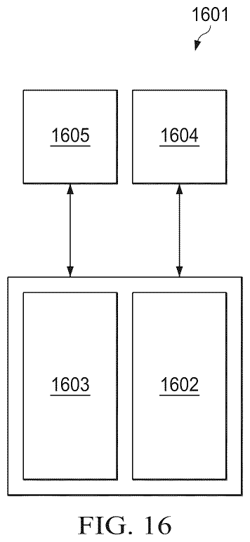

Microelectronic devices (e.g., the microelectronic device 1401 (FIG. 14 or FIG. 15)) in accordance with embodiments of the disclosure may be used in embodiments of electronic systems of the disclosure. For example, FIG. 16 is a block diagram illustrating an electronic system 1601 according to embodiments of disclosure. The electronic system 1601 may comprise, for example, a computer or computer hardware component, a server or other networking hardware component, a cellular telephone, a digital camera, a personal digital assistant (PDA), portable media (e.g., music) player, a Wi-Fi or cellular-enabled tablet such as, for example, an iPAD® or SURFACE® tablet, an electronic book, a navigation device, etc. The electronic system 1601 includes at least one memory device 1602. The memory device 1602 may comprise, for example, a microelectronic device (e.g., the microelectronic device 1401 (FIG. 14 or FIG. 15)) previously described herein. The electronic system 1601 may further include at least one electronic signal processor device 1603 (often referred to as a “microprocessor”). The electronic signal processor device 1603 may, optionally, comprise a microelectronic device (e.g., the microelectronic device 1401 (FIG. 14 or FIG. 15)) previously described herein. While the memory device 1602 and the electronic signal processor device 1603 are depicted as two (2) separate devices in FIG. 16, in additional embodiments, a single (e.g., only one) memory/processor device having the functionalities of the memory device 1602 and the electronic signal processor device 1603 is included in the electronic system 1601. In such embodiments, the memory/processor device may include a microelectronic device (e.g., the microelectronic device 1401 (FIG. 14 or FIG. 15)) previously described herein. The electronic system 1601 may further include one or more input devices 1604 for inputting information into the electronic system 1601 by a user, such as, for example, a mouse or other pointing device, a keyboard, a touchpad, a button, or a control panel. The electronic system 1601 may further include one or more output devices 1605 for outputting information (e.g., visual or audio output) to a user such as, for example, a monitor, a display, a printer, an audio output jack, a speaker, etc. In some embodiments, the input device 1604 and the output device 1605 comprise a single touchscreen device that can be used both to input information to the electronic system 1601 and to output visual information to a user. The input device 1604 and the output device 1605 may communicate electrically with one or more of the memory device 1602 and the electronic signal processor device 1603.

Embodiments of the disclosure include a microelectronic device. The microelectronic device includes two end of array (EOA) regions. The microelectronic device further includes an array region laterally interposed between the two EOA regions in a first direction. The microelectronic device also includes vertical channel access devices within the array region. The vertical channel access devices include a semiconductor pillar comprising a channel region vertically interposed between two source/drain regions. The vertical channel access devices further include a gate electrode structure laterally offset from the semiconductor pillar in a second direction orthogonal to the first direction. The gate electrode structure includes a first portion substantially linearly extending through the array region in the first direction. The gate electrode structure further includes a second portion continuous with the first portion and horizontally extending in a non-linear path within one of the two EOA regions. The vertical channel access devices also include gate dielectric material horizontally interposed between the gate structure and the semiconductor pillar.

Another embodiment of the disclosure includes a memory device. The memory device includes an array region comprising vertical channel access devices. The memory device further includes a shield plate structure vertically overlying the vertical channel access devices and substantially covering a horizontal area of the array region. The memory device also includes a shield gate structure vertically overlapping and laterally interposed between two of the vertical channel access devices, the shield gate structure operatively coupled to the shield plate structure.

Other embodiments of the disclosure include a method of forming a microelectronic device. The method includes forming semiconductor pillars within an array region and individually including a first doped region, a second doped region, and a channel region vertically between the first doped region and a second doped region, the semiconductor pillars separated from one another in a first lateral direction by first trenches. The first trenches individually include a first portion within the array region and substantially linearly extending through the array region in a second lateral direction orthogonal to the first lateral direction; and second portions continuous with the first portion and within edge of array regions neighboring the array region in the second lateral direction, the second regions each having a larger width in the first lateral direction than the first portion. The method further includes forming gate electrode structures within the first trenches. The gate electrode structures individually include a first section within the first portion of a respective one of the first trenches and substantially linearly extending through in the second lateral direction; and second sections within the second portions of the respective one of the first trenches, at least one of the second sections laterally extending in a non-linear path within at least one of the second portions of the respective one of the first trenches.

The structures, devices, and methods of the disclosure may decrease the accuracy needed for forming connections between a base control logic structure and a memory array. This may advantageously facilitate one or more of improved microelectronic device performance, reduced costs (e.g., manufacturing costs, material costs), increased miniaturization of components, and greater packaging density as compared to conventional structures, conventional devices, and conventional methods. The structures, devices, and methods of the disclosure may also improve scalability, efficiency, and simplicity as compared to conventional structures, conventional devices, and conventional methods.

While the disclosure is susceptible to various modifications and alternative forms, specific embodiments have been shown by way of example in the drawings and have been described in detail herein. However, the disclosure is not limited to the particular forms disclosed. Rather, the disclosure is to cover all modifications, equivalents, and alternatives falling within the scope of the following appended claims and their legal equivalents. Any equivalent embodiments are within the scope of this disclosure. For example, elements and features disclosed in relation to one embodiment may be combined with elements and features disclosed in relation to other embodiments of the disclosure. Various modifications of the disclosure, in addition to those shown and described herein, such as alternate useful combinations of the elements and features described, will become apparent to those skilled in the art from the description. Such modifications and embodiments also fall within the scope of the appended claims and equivalents.

What is claimed is:

1. A microelectronic device, comprising:
two end of array (EOA) regions;
an array region laterally interposed between the two EOA regions in a first direction; and
vertical channel access devices within the array region and respectively comprising:
a semiconductor pillar comprising a channel region vertically interposed between two source/drain regions;
a gate electrode structure laterally offset from the semiconductor pillar in a second direction orthogonal to the first direction, the gate electrode structure comprising:
a first portion substantially linearly extending through the array region in the first direction; and
a second portion continuous with the first portion and horizontally extending in a non-linear path within one of the two EOA regions;
gate dielectric material horizontally interposed between the gate electrode structure and the semiconductor pillar.

2. The microelectronic device of claim 1, wherein the second portion horizontally extends in a partially rectangular path including at least two parallel sides.

3. The microelectronic device of claim 2, wherein the second portion forms a hook shape.

4. The microelectronic device of claim 1, further comprising a second semiconductor pillar and a second gate electrode structure positioned laterally between the second semiconductor pillar and the gate electrode structure.

5. The microelectronic device of claim 4, wherein the gate electrode structure and the second gate electrode structure are separated in the one of the two EOA regions at an end of the second portion of the gate electrode structure.

6. The microelectronic device of claim 4, wherein the second gate electrode structure comprises:
a third portion substantially linearly extending through the array region in the first direction; and
a fourth portion continuous with the third portion and horizontally extending in a non-linear path within a second of the two EOA regions.

7. The microelectronic device of claim 6, wherein:
a first word line contact for the gate electrode structure is positioned in contact with the gate electrode structure in the one of the two EOA regions; and
a second word line contact for the second gate electrode structure is positioned in contact with the second gate electrode structure in the second of the two EOA regions.

8. The microelectronic device of claim 1, further comprising a shield gate structure laterally offset from the semiconductor pillar in the second direction on an opposite side of the semiconductor pillar from the gate electrode structure, the shield gate structure not extending into either of two the EOA regions.

9. A memory device comprising:
an array region comprising vertical channel access devices;
a shield plate structure vertically overlying the vertical channel access devices and substantially covering a horizontal area of the array region; and
a shield gate structure vertically overlapping and laterally interposed between two of the vertical channel access devices, the shield gate structure operatively coupled to the shield plate structure.

10. The memory device of claim 9, further comprising digit line structures positioned vertically between the shield plate structure and the vertical channel access devices.

11. The memory device of claim 10, wherein the digit line structures extend laterally in a direction perpendicular to the shield gate structure.

12. The memory device of claim 10, wherein shield gate structure includes a protrusion extending vertically to the shield plate structure in a region between two neighboring digit line structures of the digit line structures.

13. The memory device of claim 9, the memory device further comprising a word line structure laterally interposed between one of the two of the vertical channel access devices and a third vertical channel access device of the vertical channel access devices, the word line structure extending laterally through the array region in a direction parallel to the shield gate structure.

14. The memory device of claim 13, the memory device further comprising an edge region neighboring the array region wherein the word line structure extends into the edge region and the shield gate structure does not extend into the edge region.

15. The memory device of claim 14, wherein the word line structure includes a termination hook in the edge region.

16. The memory device of claim 15, the memory device further comprising a word line contact structure electrically connected to the termination hook in the edge region.

17. A method of forming a microelectronic device, the method comprising:
forming semiconductor pillars within an array region and individually including a first doped region, a second doped region, and a channel region vertically between the first doped region and the second doped region, the semiconductor pillars separated from one another in a first lateral direction by first trenches individually comprising;
a first portion within the array region and substantially linearly extending through the array region in a second lateral direction orthogonal to the first lateral direction; and
second portions continuous with the first portion and within edge of array regions neighboring the array region in the second lateral direction, the second doped regions each having a larger width in the first lateral direction than the first portion;
forming gate electrode structures within the first trenches and individually including:
a first section within the first portion of a respective one of the first trenches and substantially linearly extending through in the second lateral direction; and
second sections within the second portions of the respective one of the first trenches, at least one of the second sections laterally extending in a non-linear path within at least one of the second portions of the respective one of the first trenches.

18. The method of claim 17, wherein forming the semiconductor pillars separated from one another in the first lateral direction by the first trenches comprises forming the first trenches where the second portions within the edge of array regions have a width in the first lateral direction that is substantially equal to a space between laterally neighboring second portions of the first trenches.

19. The method of claim 17, wherein forming the semiconductor pillars separated from one another in the first lateral direction by the first trenches comprises forming the first trenches where the second portions within the edge of array regions are laterally staggered in the second lateral direction, such that the second portions of laterally neighboring first trenches do not laterally overlap in the first direction or the second direction.

20. The method of claim 17, wherein forming the gate electrode structures within the first trenches comprises:
forming a continuous conductive structure along sidewalls of the respective one of the first trenches, the continuous conductive structure extending along the sidewalls in the first portion and the second portion of the respective one of the first trenches; and
removing a portion of the continuous conductive structure in the second portion of the respective one of the first trenches separating the continuous conductive structure into two gate electrode structures.
